(19) United States
(12) Patent Application Publication
(10) Pub. No.: US 2015/0165563 A1
(43) Pub. Date: Jun. 18, 2015

(54) STACKED TRANSPARENT MATERIAL CUTTING WITH ULTRAFAST LASER BEAM OPTICS, DISRUPTIVE LAYERS AND OTHER LAYERS

(71) Applicant: Corning Incorporated, Corning, NY (US)

(72) Inventors: Robert George Manley, Vestal, NY (US); Sasha Marjanovic, Painted Post, NY (US); Garrett Andrew Piech, Corning, NY (US); Sergio Tsuda, Horseheads, NY (US); Robert Stephen Wagner, Corning, NY (US)

(21) Appl. No.: 14/530,457

(22) Filed: Oct. 31, 2014

Related U.S. Application Data
(60) Provisional application No. 61/917,092, filed on Dec. 17, 2013.
(60) Provisional application No. 62/022,896, filed on Jul. 10, 2014.

(51) Int. Cl. B23K 26/40; C03B 33/00; H05K 5/03; C03B 33/07; C03C 15/00; B32B 17/00; C03B 33/08

(52) U.S. Cl. CPC B23K 26/4075; B32B 17/00; C03B 33/00; C03B 33/082; C03B 33/078; C03C 15/00; H05K 5/03; B32B 2457/20

(57) ABSTRACT

A method of laser drilling, forming a perforation, cutting, separating or otherwise processing a material includes focusing a pulsed laser beam into a laser beam focal line, and directing the laser beam focal line into a workpiece comprising a stack including at least: a first layer, facing the laser beam, the first layer being the material to be laser processed, a second layer comprising a carrier layer, and a laser beam disruption element located between the first and second layers, the laser beam focal line generating an induced absorption within the material of the first layer, the induced absorption producing a defect line along the laser beam focal line within the material of the first layer. The beam disruption element may be a beam disruption layer or a beam disruption interface.

### RELATED APPLICATIONS

This application claims the benefit of U.S. Provisional Application No. 61/917,092 filed on Dec. 17, 2013 as well as the benefit of U.S. Provisional Application No. 62/022,896 filed on Jul. 10, 2014, the entire disclosures of which are incorporated herein by reference.

### BACKGROUND

In recent years, precision micromachining and its improvement of process development to meet customer demand to reduce the size, weight and material cost of leading-edge devices has led to fast pace growth in high-tech industries in flat panel displays for touch screens, tablets, smartphones and TVs, where ultrafast industrial lasers are becoming important tools for applications requiring high precision.

There are various known ways to cut glasses. In conventional laser glass cutting processes, the separation of glass relies on laser scribing or perforation followed by separation with mechanical force or thermal stress-induced crack propagation. Nearly all current laser cutting techniques exhibit one or more shortcomings, including:

(1) limitations in their ability to perform a free form shaped cut of thin glass on a carrier due to a large heat-affected zone (HAZ) associated with the long laser pulses (nanosecond scale or longer) used for cutting,

(2) production of thermal stress that often results in cracking of the glass surface near the region of laser illumination due to the generation of shock waves and uncontrolled material removal and,

(3) creation of sub-surface damage in the glass that extends hundreds of microns (or more) glass below the surface of the glass, resulting in defect sites at which crack propagation can initiate,

(4) difficulties in controlling the depth of the cut (e.g., to within tens of microns).

### SUMMARY

The embodiments disclosed herein relate to a method and an apparatus to create small (micron and smaller) “holes” in transparent materials (glass, sapphire, etc) for the purpose of drilling, cutting, separating, perforating, or otherwise processing the materials. More particularly, an ultrashort (i.e., from 10⁻¹⁰ to 10⁻¹⁵ second) pulse laser beam (wavelengths such as, for example, 1064, 532, 355 or 266 nanometers) is focused to an energy density above the threshold needed to create a defect in the region of focus at the surface of or within the transparent material. By repeating the process, a series of laser-induced defects aligned along a predetermined path can be created. By spacing the laser-induced features sufficiently close together, a controlled region of mechanical weakness within the transparent material can be created and the transparent material can be precisely fractured or separated (mechanically or thermally) along the path defined by the series of laser-induced defects. The ultrashort laser pulse(s) may be optionally followed by a carbon dioxide (CO₂) laser or other source of thermal stress to effect fully automated separation of a transparent material or part from a substrate sheet, for example.

In certain applications where transparent materials are bonded together to form a stack or layered structure, it is often desirable to selectively “cut” to the boundary of a particular layer without disturbing underlying layers. This may be performed with the addition of a reflective or absorptive (for the desired wavelength) material or layer at the preferred depth of cut. A reflective layer may be formed by depositing a thin material (for example, aluminum, copper, silver, gold, etc). A scattering or reflective layer is preferential as it scatters or reflects the incident energy (as opposed to absorbing and thermally dissipating the incident energy). In this manner, the depth of the cut may be controlled with no damage to the underlying layers. In one application, a transparent material is bonded to a carrier substrate and a reflective or absorptive layer is formed between the transparent material and carrier substrate. The reflective or absorptive layer enables cutting of the transparent material without damage to the underlying carrier substrate, which may then be reused. A carrier substrate is a support layer that is used to provide mechanical rigidity or ease of handling to allow the layers on top of the carrier substrate to be modified, cut, or drilled by one or more laser process steps described herein.

In one embodiment, a method of laser drilling, cutting, separating or otherwise processing a material includes forming a laser beam focal line in a workpiece, the laser beam focal line being formed from a pulsed laser beam, the workpiece comprising a plurality of materials including: a first layer facing the laser beam, the first layer being the material to be laser processed, a second layer, and a beam disruption layer located between the first and second layers. The laser beam focal line generates an induced absorption within the material of the first layer, the induced absorption producing a defect line along the laser beam focal line within the material of the first layer. The beam disruption layer can be, for example, a carrier layer.

In another embodiment, a method of laser processing includes forming a laser beam focal line in a workpiece, the laser beam focal line being formed from a pulsed laser beam, the workpiece including a glass layer and a transparent electrically conductive layer, the laser beam focal line generating an induced absorption within the workpiece, the induced absorption producing a defect line along the laser beam focal line through the transparent electrically conductive layer and into the glass layer.

In yet another embodiment, a method of laser processing includes forming a laser beam focal line in a workpiece, the laser beam focal line being formed from a pulsed laser beam, the workpiece comprising a plurality of glass layers, the workpiece including a transparent protective layer between each of the glass layers, the laser beam focal line generating an induced absorption within the workpiece, the induced absorption producing a defect line along the laser beam focal line within the workpiece.

In still another embodiment, a method of laser processing includes forming a laser beam focal line in a workpiece, the laser beam focal line being formed from a pulsed laser beam, the workpiece including a plurality of glass layers, the workpiece including an air gap between each of the glass layers, the laser beam focal line generating an induced absorption within the workpiece, the induced absorption producing a defect line along the laser beam focal line within the workpiece.

In yet another embodiment, a method of laser processing includes forming a laser beam focal line in a workpiece, the laser beam focal line being formed from a pulsed laser beam. The workpiece has a glass layer, the laser beam focal line generates an induced absorption within the glass layer, and the induced absorption produces a defect line along the laser beam focal line within the glass layer. The method also includes translating the workpiece and the laser beam relative to each other along a contour, thereby forming a plurality of defect lines along the contour, and applying an acid etch process, the acid etch process separating the glass layer along the contour.

Use of acid etching allows for release of complex contours, such as holes or slots or other interior contours inside a larger piece, which can be difficult to do with high speed and high yield with just laser methods. In addition, use of acid etching allows for formation of holes with dimensions that are practical for metallization or other chemical coating. Holes produced by the laser are enlarged in parallel to a target diameter in a parallel process, which may be faster than using a laser to drill out the holes to a large diameter by using further laser exposure.

Acid etching creates a stronger part than use of the laser only, by blunting any micro-cracks or damage that may be caused by prolonged exposure to the laser.

In still another embodiment, a method of laser processing includes forming a laser beam focal line in a workpiece, the laser beam focal line being formed from a pulsed laser beam. The workpiece has a glass layer, the laser beam focal line generates an induced absorption within the workpiece, and the induced absorption produces a defect line along the laser beam focal line within the workpiece. The method also includes translating the workpiece and the laser beam relative to each other along a closed contour, thereby forming a plurality of defect lines along the closed contour, and applying an acid etch process, the acid etch process facilitating removal of a portion of the glass layer circumscribed by the closed contour.

In yet another embodiment, a method of laser processing includes forming a laser beam focal line in a workpiece, the laser beam focal line being formed from a pulsed laser beam, the workpiece having a glass layer, the laser beam focal line generating an induced absorption within the workpiece, the induced absorption producing a defect line along the laser beam focal line within the workpiece, translating the workpiece and the laser beam relative to each other along a contour, thereby forming a plurality of defect lines along the contour, and directing an infrared laser beam along the contour. The infrared laser beam can be produced by a carbon dioxide (CO₂) laser or other infrared laser.

Laser cutting of thin glasses in accordance with the present disclosure has advantages that include minimization or prevention of crack creation at or near the region of ablation and the ability to perform free form cuts of arbitrary shape. It is important that edge cracking and residual edge stress are avoided in parts separated from glass substrates for applications such as flat panel displays because parts have a pronounced propensity to break from an edge, even when stress is applied to the center. The high peak power of ultrafast lasers combined with tailored beam delivery in the method described herein can avoid these problems because the present method is a “cold” ablation technique that cuts without a deleterious heat effect. Laser cutting by ultrafast lasers according to the present method produces essentially no residual stress in the glass.

The present embodiments further extend to:

A method of laser processing comprising:
forming a laser beam focal line in a workpiece, the laser beam focal line being formed from a pulsed laser beam,
the workpiece comprising: a first layer, a second layer, and a beam disruption element located between the first and second layers; and
   the laser beam focal line generating an induced absorption within the first layer, the induced absorption producing a defect line along the laser beam focal line within the first layer.

The present embodiments further extend to:

A method of laser processing comprising:
forming a laser beam focal line in a workpiece, the laser beam focal line being formed from a pulsed laser beam, the workpiece comprising a glass layer and a transparent electrically conductive layer, the laser beam focal line generating an induced absorption within the workpiece, the induced absorption producing a defect line along the laser beam focal line through the transparent electrically conductive layer and into the glass layer.

The present embodiments further extend to:

A method of laser processing comprising:

forming a laser beam focal line in a workpiece, the laser beam focal line being formed from a pulsed laser beam, the workpiece comprising a plurality of glass layers, the workpiece including a transparent protective layer between each of the glass layers, the laser beam focal line generating an induced absorption within the workpiece, the induced absorption producing a defect line along the laser beam focal line within the workpiece.

The present embodiments further extend to:

A method of laser processing comprising:
forming a laser beam focal line in a workpiece, the laser beam focal line being formed from a pulsed laser beam, the workpiece comprising a plurality of glass layers, the workpiece including an air gap between each of the glass layers, the laser beam focal line generating an induced absorption within the workpiece, the induced absorption producing a defect line along the laser beam focal line within the workpiece.

The present embodiments further extend to:

A method of laser processing comprising:
forming a laser beam focal line in a workpiece, the laser beam focal line being formed from a pulsed laser beam,
the workpiece having a glass layer, the laser beam focal line generating an induced absorption within the glass layer, the induced absorption producing a defect line along the laser beam focal line within the glass layer;
translating the workpiece and the laser beam relative to each other along a contour, thereby forming a plurality of defect lines in the glass layer along the contour; and
applying an acid etch process, the acid etch process separating the glass layer along the contour.

The present embodiments further extend to:

A method of laser processing comprising:
forming a laser beam focal line in a workpiece, the laser beam focal line being formed from a pulsed laser beam,
the workpiece having a glass layer, the laser beam focal line generating an induced absorption within the workpiece, the induced absorption producing a defect line along the laser beam focal line within the workpiece;
translating the workpiece and the laser beam relative to each other along a closed contour, thereby forming a plurality of defect lines along the closed contour; and
applying an acid etch process, the acid etch process facilitating removal of a portion of the glass layer circumscribed by the closed contour.

The present embodiments further extend to:

A method of laser processing comprising:
forming a laser beam focal line in a workpiece, the laser beam focal line being formed from a pulsed laser beam,
the workpiece having a glass layer, the laser beam focal line generating an induced absorption within the workpiece, the induced absorption producing a defect line along the laser beam focal line within the workpiece;
translating the workpiece and the laser beam relative to each other along a contour, thereby forming a plurality of defect lines along the contour; and
directing an infrared laser along the contour.

The present embodiments further extend to:

A method of forming a perforation comprising:

(i) providing a multilayer structure, the multilayer structure including a beam disruption element disposed on a carrier and a first layer disposed on the beam disruption element;

(ii) focusing a laser beam with wavelength λ on a first portion of the first layer, the first layer being transparent to the wavelength λ, the focusing forming a region of high laser intensity within the first layer, the high laser intensity being sufficient to effect nonlinear absorption within the region of high laser intensity, the beam disruption element preventing occurrence of nonlinear absorption in the carrier material or other layer disposed on the side of the beam disruption element opposite the first layer, the nonlinear absorption enabling transfer of energy from the laser beam to the first layer within the region of high intensity, the transfer of energy causing creation of a first perforation in the first layer in the region of high laser intensity, the first perforation extending in the direction of propagation of the laser beam;

(iii) focusing the laser beam on a second portion of the first layer; and

(iv) repeating step (ii) to form a second perforation in the second portion of the substrate, the second perforation extending in the direction of propagation of the laser beam, the beam disruption element preventing occurrence of nonlinear absorption in the carrier material or other layer disposed on the side of the beam disruption element opposite the first layer during the formation of the second perforation.

### BRIEF DESCRIPTION OF THE DRAWINGS

The foregoing will be apparent from the following more particular description of the example embodiments, as illustrated in the accompanying drawings in which like reference characters refer to the same parts throughout the different views. The drawings are not necessarily to scale, emphasis instead being placed upon illustrating the representative embodiments.

FIG. 1 is an illustration of a stack of three layers: a thin material A facing the laser energy, a modified interface, and a thick material B, the modified interface disrupting the laser energy form interacting with the portion of the stack on the side of the modified interface remote from the laser beam.

FIGS. 2A and 2B are illustrations of positioning of the laser beam focal line, i.e., laser processing of a material transparent to the laser wavelength due to the induced absorption along the focal line.

FIG. 3A is an illustration of an optical assembly for laser processing.

FIG. 3B-1-3B-4 are an illustration of various possibilities to process the substrate by forming the laser beam focal line at different positions within the transparent material relative to the substrate.

FIG. 4 is an illustration of a second optical assembly for laser processing.

FIGS. 5A and 5B are illustrations of a third optical assembly for laser drilling.

FIG. 6 is a schematic illustration of a fourth optical assembly for laser processing.

FIGS. 7A and 7B depict laser emission as a function of time for a picosecond laser. Each emission is characterized by a pulse “burst” which may contain one or more sub-pulses. Times corresponding to pulse duration, separation between pulses, and separation between bursts are illustrated.

FIG. 8 is a comparison between a focused Gaussian beam and a Bessel beam incident upon a glass-air-glass composite structure.

FIG. 9 is an illustration of stacking with transparent protective layers to cut multiple sheets while reducing abrasion or contamination.

FIG. 10 is an illustration of an air gap and cutting of encapsulated devices.

FIG. 11 is an illustration of cutting of interposers or windows with laser perforation then etch or laser perforation and CO₂ laser release.

FIG. 12 is an illustration of cutting an article such as electrochromic glass coated with transparent electrically conductive layers (e.g. indium tin oxide (ITO)).

FIG. 13 is an illustration of precision cutting of some layers in a stack while not damaging others.

FIG. 14A is a side-view illustration of an example laminate stack including plastic film outer layers with glass or plastic inner layers.

FIG. 14B illustrates laser perforations made through all layers of the laminate illustrated in FIG. 14A using disclosed laser methods.

FIG. 14C illustrates defect lines that result from the laser perforations 1450.

FIG. 15 is a top-view illustration of the laminate shown in FIGS. 14A-C.

FIG. 16A is a side-view illustration of a laminate similar to the one shown in FIGS. 14A-C, but with laser perforations extending only through some layers of the laminate.

FIG. 16B shows defect lines corresponding to the laser perforations of FIG. 16A extending only to a specific depth in the laminate.

### DETAILED DESCRIPTION

A description of example embodiments follows.

The embodiment described herein relates to a method and apparatus for optically producing high precision cuts in or through transparent materials. Sub-surface damage may be limited to the order of 100 μm in depth or less, or 75 μm in depth or less, or 60 μm in depth or less, or 50 μm in depth or less, and the cuts may produce only low debris. Cutting of a transparent material with a laser in accordance with the present disclosure may also be referred to herein as drilling or laser drilling or laser processing. Within the context of the present disclosure, a material is substantially transparent to the laser wavelength when the absorption is less than about 10%, preferably less than about 1% per mm of material depth at this wavelength.

In accordance with methods described below, in a single pass, a laser can be used to create highly controlled full line perforation through the material, with extremely little (<75 μm, often <50 μm) subsurface damage and debris generation. This is in contrast to the typical use of spot-focused laser to ablate material, where multiple passes are often necessary to completely perforate the glass thickness, large amounts of debris are formed from the ablation process, and more extensive sub-surface damage (>100 μm) and edge chipping occur. As used herein, subsurface damage refers to the maximum size (e.g. length, width, diameter) of structural imperfections in the perimeter surface of the part separated from the substrate or material subjected to laser processing in accordance with the present disclosure. Since the structural imperfections extend from the perimeter surface, subsurface damage may also be regarded as the maximum depth from the perimeter surface in which damage from laser processing in accordance with the present disclosure occurs. The perimeter surface of the separated part may be referred to herein as the edge or the edge surface of the separated part. The structural imperfections may be cracks or voids and represent points of mechanical weakness that promote fracture or failure of the part separated from the substrate or material. By minimizing the size of subsurface damage, the present method improves the structural integrity and mechanical strength of separated parts.

Thus, it is possible to create microscopic (i.e., <2 μm and >100 nm in diameter, and in some embodiments <0.5 μm and >100 nm) elongated defect lines (also referred to herein as perforations or damage tracks) in transparent material using one or more high energy pulses or one or more bursts of high energy pulses. The perforations represent regions of the substrate material modified by the laser. The laser-induced modifications disrupt the structure of the substrate material and constitute sites of mechanical weakness. Structural disruptions include compaction, melting, dislodging of material, rearrangements, and bond scission. The perforations extend into the interior of the substrate material and have a cross-sectional shape consistent with the cross-sectional shape of the laser (generally circular). The average diameter of the perforations may be in the range from 0.1 μm to 50 μm, or in the range from 1 μm to 20 μm, or in the range from 2 μm to 10 μm, or in the range from 0.1 μm to 5 μm. In some embodiments, the perforation is a “through hole”, which is a hole or an open channel that extends from the top to the bottom of the substrate material. In some embodiments, the perforation may not be a continuously open channel and may include sections of solid material dislodged from the substrate material by the laser. The dislodged material blocks or partially blocks the space defined by the perforation. One or more open channels (unblocked regions) may be dispersed between sections of dislodged material. The diameter of the open channels is may be <1000 nm, or <500 nm, or <400 nm, or <300 nm or in the range from 10 nm to 750 nm, or in the range from 100 nm to 500 nm. The disrupted or modified area (e.g, compacted, melted, or otherwise changed) of the material surrounding the holes in the embodiments disclosed herein, preferably has diameter of <50 μm (e.g, <10 μm).

The individual perforations can be created at rates of several hundred kilohertz (several hundred thousand perforations per second, for example). Thus, with relative motion between the laser source and the material these perforations can be placed adjacent to one another (spatial separation varying from sub-micron to several or even tens of microns as desired). This spatial separation is selected in order to facilitate cutting.

In addition, through judicious selection of optics, selective cutting of individual layers of stacked transparent materials can be achieved. Micromachining and selective cutting of a stack of transparent materials is accomplished with precise control of the depth of cut through selection of an appropriate laser source and wavelength along with beam delivery optics, and the placement of a beam disruption element at the boundary of a desired layer. The beam disruption element may be a layer of material or an interface. The beam disruption element may be referred to herein as a laser beam disruption element, disruption element or the like. Embodiments of the beam disruption element may be referred to herein as a beam disruption layer, laser beam disruption layer, disruption layer, beam disruption interface, laser beam disruption interface, disruption interface, or the like.

The beam disruption element reflects, absorbs, scatters, defocuses or otherwise interferes with an incident laser beam to inhibit or prevent the laser beam from damaging or otherwise modifying underlying layers in the stack. In one embodiment, the beam disruption element underlies the layer of transparent material in which laser drilling will occur. As used herein, the beam disruption element underlies the transparent material when placement of the beam disruption element is such that the laser beam must pass through the transparent material before encountering the beam disruption element. The beam disruption element may underlie and be directly adjacent to the transparent layer in which laser drilling will occur. Stacked materials can be micromachined or cut with high selectivity by inserting a layer or modifying the interface such that a contrast of optical properties exists between different layers of the stack. By making the interface between materials in the stack more reflective, absorbing, defocusing, and/or scattering at the laser wavelengths of interest, cutting can be confined to one portion or layer of the stack.

The wavelength of the laser is selected so that the material within the stack to be laser processed (drilled, cut, ablated, damaged or otherwise appreciably modified by the laser) is transparent to the laser wavelength. In one embodiment, the material to be processed by the laser is transparent to the laser wavelength if it absorbs less than 10% of the intensity of the laser wavelength per mm of thickness of the material. In another embodiment, the material to be processed by the laser is transparent to the laser wavelength if it absorbs less than 5% of the intensity of the laser wavelength per mm of thickness of the material. In still another, the material to be processed by the laser is transparent to the laser wavelength if it absorbs less than 2% of the intensity of the laser wavelength per mm of thickness of the material. In yet another embodiment, the material to be processed by the laser is transparent to the laser wavelength if it absorbs less than 1% of the intensity of the laser wavelength per mm of thickness of the material.

The selection of the laser source is further predicated on the ability to induce multi-photon absorption (MPA) in the transparent material. MPA is the simultaneous absorption of multiple photons of identical or different frequencies in order to excite a material from a lower energy state (usually the ground state) to a higher energy state (excited state). The excited state may be an excited electronic state or an ionized state. The energy difference between the higher and lower energy states of the material is equal to the sum of the energies of the two or more photons. MPA is a nonlinear process that is generally several orders of magnitude weaker than linear absorption. It differs from linear absorption in that the strength of MPA depends on the square or higher power of the light intensity, thus making it a nonlinear optical process. At ordinary light intensities, MPA is negligible. If the light intensity (energy density) is extremely high, such as in the region of focus of a laser source (particularly a pulsed laser source), MPA becomes appreciable and leads to measurable effects in the material within the region where the energy density of the light source is sufficiently high. Within the focal region, the energy density may be sufficiently high to result in ionization.

At the atomic level, the ionization of individual atoms has discrete energy requirements. Several elements commonly used in glass (e.g., Si, Na, K) have relatively low ionization energies (˜5 eV). Without the phenomenon of MPA, a wavelength of about 248 nm would be required to create linear ionization at ˜5 eV. With MPA, ionization or excitation between states separated in energy by ˜5 eV can be accomplished with wavelengths longer than 248 nm. For example, photons with a wavelength of 532 nm have an energy of ˜2.33 eV, so two photons with wavelength 532 nm can induce a transition between states separated in energy by ˜4.66 eV in two-photon absorption (TPA), for example. Thus, atoms and bonds can be selectively excited or ionized in the regions of a material where the energy density of the laser beam is sufficiently high to induce nonlinear TPA of a laser wavelength having half the required excitation energy, for example.

MPA can result in a local reconfiguration and separation of the excited atoms or bonds from adjacent atoms or bonds. The resulting modification in the bonding or configuration can result in non-thermal ablation and removal of matter from the region of the material in which MPA occurs. This removal of matter creates a structural defect (e.g. a defect line, damage line, or “perforation”) that mechanically weakens the material and renders it more susceptible to cracking or fracturing upon application of mechanical or thermal stress. By controlling the placement of perforations, a contour or path along which cracking occurs can be precisely defined and precise micromachining of the material can be accomplished. The contour defined by a series of perforations may be regarded as a fault line and corresponds to a region of structural weakness in the material. In one embodiment, micromachining includes separation of a part from the material processed by the laser, where the part has a precisely defined shape or perimeter determined by a closed contour of perforations formed through MPA effects induced by the laser. As used herein, the term closed contour refers to a perforation path formed by the laser line, where the path intersects with itself at some location. An internal contour is a path formed where the resulting shape is entirely surrounded by an outer portion of material.

The laser is an ultrashort pulsed laser (pulse durations on the order tens of picoseconds or shorter) and can be operated in pulse mode or burst mode. In pulse mode, a series of nominally identical single pulses is emitted from the laser and directed to the workpiece. In pulse mode, the repetition rate of the laser is determined by the spacing in time between the pulses. In burst mode, bursts of pulses are emitted from the laser, where each burst includes two or more pulses (of equal or different amplitude). In burst mode, pulses within a burst are separated by a first time interval (which defines a pulse repetition rate for the burst) and the bursts are separated by a second time interval (which defines a burst repetition rate), where the second time interval is typically much longer than the first time interval. As used herein (whether in the context of pulse mode or burst mode), time interval refers to the time difference between corresponding parts of a pulse or burst (e.g. leading edge-to-leading edge, peak-to-peak, or trailing edge-to-trailing edge). Pulse and burst repetition rates are controlled by the design of the laser and can typically be adjusted, within limits, by adjusting operating conditions of the laser. Typical pulse and burst repetition rates are in the kHz to MHz range.

The laser pulse duration (in pulse mode or for pulses within a burst in burst mode) may be 10⁻¹⁰ s or less, or 10⁻¹¹ s or less, or 10⁻¹² s or less, or 10⁻¹³ s or less. In the exemplary embodiments described herein, the laser pulse duration is greater than 10⁻¹⁵.

The perforations may be spaced apart and precisely positioned by controlling the velocity of a substrate or stack relative to the laser through control of the motion of the laser and/or the substrate or stack. As an example, in a thin transparent substrate moving at 200 mm/sec exposed to a 100 kHz series of pulses (or bursts of pulses), the individual pulses would be spaced 2 microns apart to create a series of perforations separated by 2 microns. This defect line (perforation) spacing is sufficiently close to allow for mechanical or thermal separation along the contour defined by the series of perforations. Distance between adjacent defect lines along the direction of the fault lines can, for example, be in range from 0.25 μm to 50 μm, or in the range from 0.50 μm to about 20 μm, or in the range from 0.50 μm to about 15 μm, or in the range from 0.50 μm to 10 μm, or in the range from 0.50 μm to 3.0 μm or in the range from 3.0 μm to 10 μm.

### Thermal Separation:

In some cases, a fault line created along a contour defined by a series of perforations or defect lines is not enough to separate the part spontaneously, and a secondary step may be necessary. If so desired, a second laser can be used to create thermal stress to separate it, for example. In the case of low stress glass such as Corning Eagle XG or Corning glass code 2318 before it has undergone chemical strengthening from ion-exchange, separation can be achieved, after the creation of a fault line, by application of mechanical force or by using a thermal source (e.g., an infrared laser, for example a CO₂ laser) to create thermal stress and force a part to separate from a substrate. Another option is to have the CO₂ laser only start the separation and then finish the separation manually. The optional CO₂ laser separation can be achieved, for example, with a defocused continuous wave (cw) laser emitting at 10.6 μm and with power adjusted by controlling its duty cycle. Focus change (i.e., extent of defocusing up to and including focused spot size) is used to vary the induced thermal stress by varying the spot size. Defocused laser beams include those laser beams that produce a spot size larger than a minimum, diffraction-limited spot size on the order of the size of the laser wavelength. For example, defocused spot sizes (1/e² diameter) of 2 to 12 mm, or about 7 mm, 2 mm and 20 mm can be used for CO₂ lasers, for example, whose diffraction-limited spot size is much smaller given the emission wavelength of 10.6 μm.

### Etching:

Acid etching can be used, for example, to separate a workpiece having a glass layer, for example. In one embodiment, for example, the acid used can be 10% HF/15% HNO₃ by volume. The parts can be etched for 53 minutes at a temperature of 24-25° C. to enlarge the diameter of the holes formed via MPA with the laser to ˜100 μm, for example. The laser-perforated parts can be immersed in this acid bath, and ultrasonic agitation at a combination of 40 kHz and 80 kHz frequencies, for example, can used to facilitate penetration of fluid and fluid exchange in the holes. In addition, manual agitation of the part within the ultrasonic field can be made to prevent standing wave patterns from the ultrasonic field from creating “hot spots” or cavitation related damage on the part. The acid composition and etch rate can be intentionally designed to slowly etch the part—a material removal rate of only 1.9 μm/minute, for example. An etch rate of less than about 2 μm/minute, for example, allows acid to fully penetrate the narrow holes and agitation to exchange fresh fluid and remove dissolved material from the holes which are very narrow when initially formed by the laser. Once the acid penetrates the holes, and the holes enlarge to a size which connects them to an adjacent hole, then the perforated contour will separate from the remainder of the substrate. For example, this allows an interior feature such as a hole or a slot to be dropped out from a larger part, or a window to be dropped out from a larger “frame” containing it.

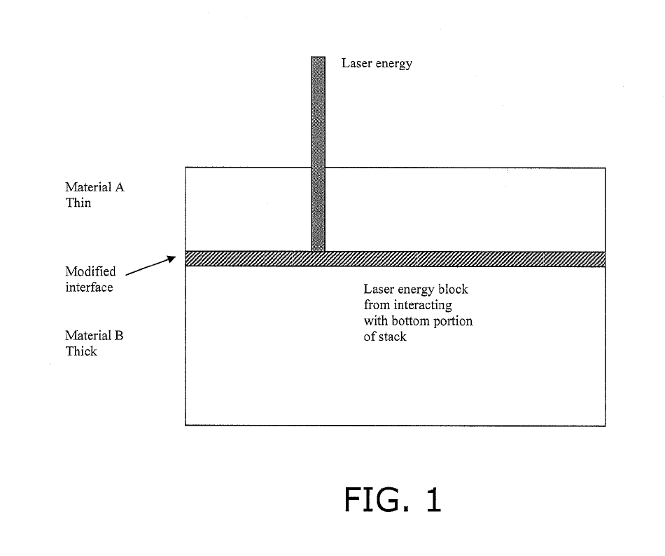

In the embodiment shown in FIG. 1, precise control of the depth of cut in a multilayer stack is achieved by inclusion of a beam disruption element in the form of a beam disruption interface (labeled “modified interface”). The beam disruption interface prevents the laser radiation from interacting with portions of the multilayer stack beyond the position of the disruption interface.

In one embodiment, the beam disruption element is positioned immediately below the layer of the stack in which modification via two-(or multi-)photon absorption will occur. Such a configuration is shown in FIG. 1, where the beam disruption element is a modified interface positioned immediately below material A and material A is the material in which formation of perforations through the two-(or multi-)photon absorption mechanism described herein will occur. As used herein, reference to a position below or lower than another position assumes that the top or uppermost position is the surface of the multilayer stack upon which the laser beam is first incident. In FIG. 1, for example, the surface of material A that is closest to the laser source is the top surface and placement of the beam disruption element below material A means that the laser beam traverses material A before interacting with the beam disruption element.

The beam disruption element has different optical properties than the material to be cut. For example, the beam disruption element may be a defocusing element, a scattering element, a translucent element, a diffracting element, an absorbing element, or a reflective element. A defocusing element is an interface or a layer comprising a material that prevents the laser light from forming the laser beam focal line on or below the defocusing element. The defocusing element may be comprised of a material or interface with refractive index inhomogeneities that scatter or perturb the wavefront of the optical beam. A translucent element is an interface or layer of material that allows light to pass through, but only after scattering or attenuating the laser beam to lower the energy density sufficiently to prevent formation of a laser beam focal line in portions of the stack on the side of the translucent element that are remote from the laser beam. In one embodiment, the translucent element effects scattering or deviating of at least 10% of the light rays of the laser beam.

More specifically, the reflectivity, absorptivity, defocusing, diffractivity, attenuation, and/or scattering of the disruption element can be employed to create a barrier or impediment to the laser radiation. The laser beam disruption element can be created by several means. If the optical properties of the overall stack system are not of a concern, then one or more thin films can be deposited as a beam disruption layer(s) between the desired two layers of the stack, where the one or more thin films absorb, scatter, defocus, attenuate, reflects, diffracts, and/or dissipates more of the laser radiation than the layer immediately above it to protect layers below the beam disruption layer(s) from receiving excessive energy density from the laser source. If the optical properties of the entire stack system do matter, the beam disruption element can be implemented as a notch filter. This can be done by several methods:
a) creating structures at the beam disruption layer or interface (e.g. via thin film growth, thin film patterning, or surface patterning) such that diffraction of incident laser radiation at a particular wavelength or range of wavelengths occurs;
b) creating structures at the beam disruption layer or interface (e.g. via thin film growth, thin film patterning, or surface pattering) such that scattering of incident laser radiation occurs (e.g. a textured surface);
c) creating structures at the beam disruption layer or interface (e.g. via thin film growth, thin film patterning, or surface pattering) such that attenuated phase-shifting of laser radiation occurs; and
d) creating a distributed Bragg reflector via thin-film stack at the beam disruption layer or interface to reflect only laser radiation.

It is not necessary that the absorption, reflection, diffraction, scattering, attenuation, defocusing etc. of the laser beam by the beam disruption element be complete. It is only necessary that the effect of the beam disruption element on the laser beam is sufficient to reduce the energy density or intensity of the focused laser beam to a level below the threshold required for cutting, ablation, perforating etc. of the layers in the stack protected by (underlying) the beam disruption element. In one embodiment, the beam disruption element reduces the energy density or intensity of the focused laser beam to a level below the threshold needed to induce two-(or multi-)photon absorption. The beam disruption layer or beam disruption interface may be configured to absorb, reflect, diffract, or scatter the laser beam, where the absorption, reflection, diffraction, or scattering are sufficient to reduce the energy density or intensity of the laser beam transmitted to the carrier (or other underlying layer) to a level below the level needed to induce nonlinear absorption in the carrier or underlying layer.

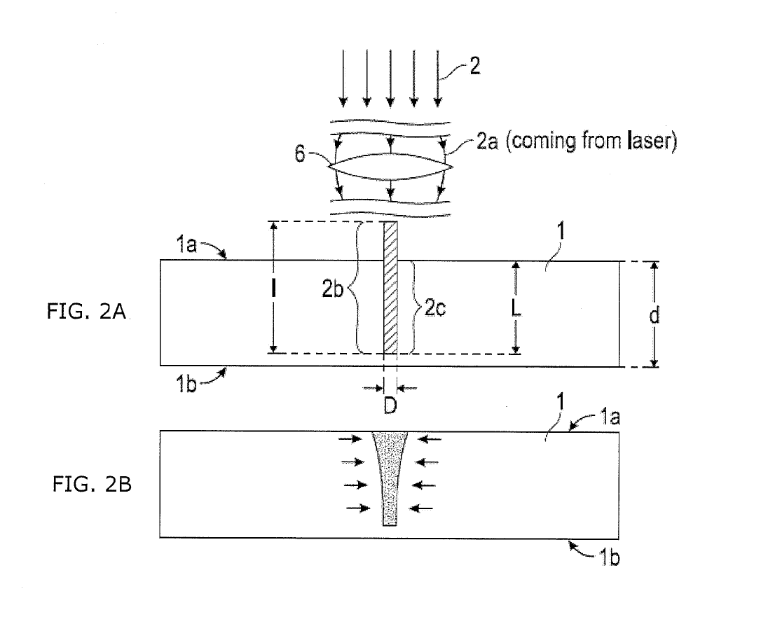

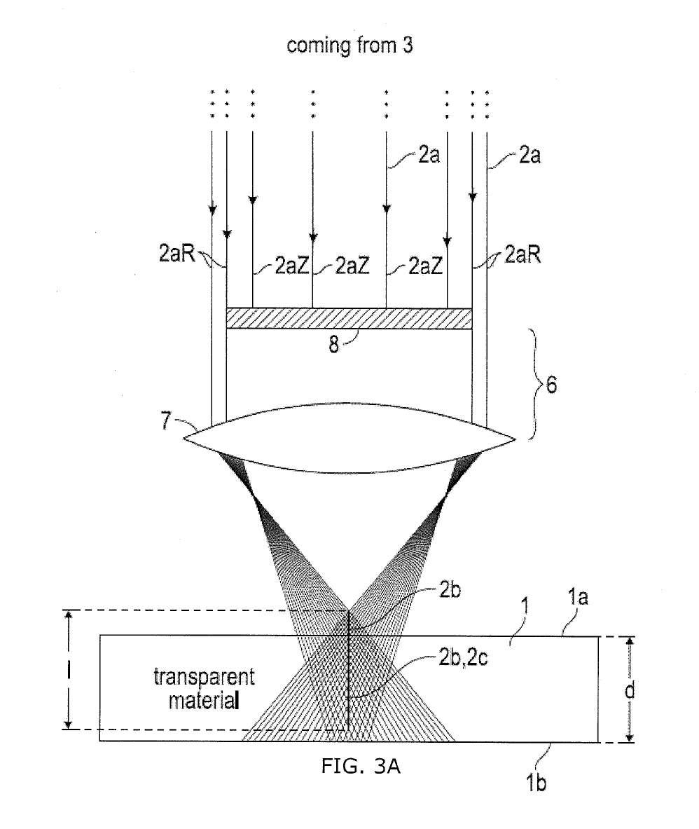

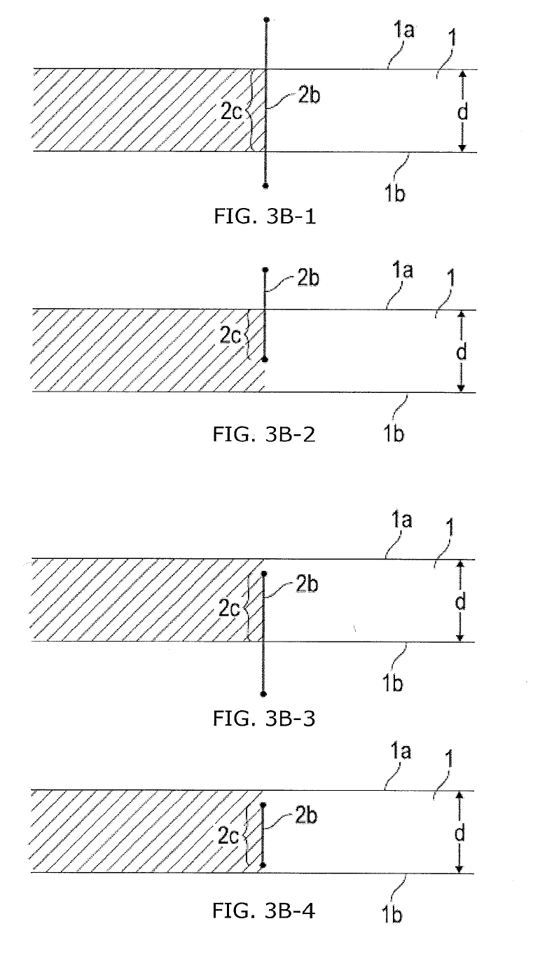

Turning to FIGS. 2A and 2B, a method of laser drilling a material includes focusing a pulsed laser beam 2 into a laser beam focal line 2b, viewed along the beam propagation direction. Laser beam focal line 2b is a region of high energy density. As shown in FIG. 3A, laser 3 (not shown) emits laser beam 2, which has a portion 2a incident to optical assembly 6. The optical assembly 6 turns the incident laser beam into a laser beam focal line 2b on the output side over a defined expansion range along the beam direction (length l of the focal line).

Layer 1 is the layer of a multilayer stack in which internal modifications by laser processing and two-(or multi-)photon absorption is to occur. Layer 1 is a component of a larger multilayer workpiece (the balance of which is not shown), which typically includes a substrate or carrier upon which a multilayer stack is formed. Layer 1 is the layer within the multilayer stack in which holes, cuts, or other features are to be formed through two-(or multi-)photon absorption assisted ablation or modification as described herein. In FIG. 1, for example, Material A corresponds to layer 1 and Material B is a layer underlying the beam disruption element. The layer 1 is positioned in the beam path to at least partially overlap the laser beam focal line 2b of laser beam 2. Reference 1a designates the surface of the layer 1 facing (closest or proximate to) the optical assembly 6 or the laser, respectively, and reference 1b designates the reverse surface of layer 1 (the surface remote, or further away from, optical assembly 6 or the laser). The thickness of the layer 1 (measured perpendicularly to the planes 1a and 1b, i.e., to the substrate plane) is labeled with d.

As FIG. 2A depicts, layer 1 is aligned substantially perpendicular to the longitudinal beam axis and thus behind the same focal line 2b produced by the optical assembly 6 (the substrate is perpendicular to the plane of the drawing). Viewed along the beam direction, the layer 1 is positioned relative to the focal line 2b in such a way that the focal line 2b (viewed in the direction of the beam) starts before the surface 1a of the layer 1 and stops before the surface 1b of the layer 1, i.e. focal line 2b terminates within the layer 1 and does not extend beyond surface 1b. In the overlapping area of the laser beam focal line 2b with layer 1, i.e. in the portion of layer 1 overlapped by focal line 2b, the laser beam focal line 2b generates nonlinear absorption in layer 1, (assuming suitable laser intensity along the laser beam focal line 2b, which intensity is ensured by adequate focusing of laser beam 2 on a section of length l (i.e. a line focus of length l)), which defines a section 2c (aligned along the longitudinal beam direction) along which an induced nonlinear absorption is generated in the layer 1). Such line focus can be created by several ways, for example, Bessel beams, Airy beams, Weber beams and Mathieu beams (i.e., non-diffractive beams), whose field profiles are typically given by special functions that decay more slowly in the transverse direction (i.e. direction of propagation) than the Gaussian function. The induced nonlinear absorption results in formation of a defect line in layer 1 along section 2c. The formation of the defect lines is not only local, but rather may extend over the entire length of the section 2c of the induced absorption. The length of section 2c (which corresponds to the length of the overlapping of laser beam focal line 2b with layer 1) is labeled with reference L. The average diameter or extent of the section of the induced absorption 2c (or the sections in the material of layer 1 undergoing the defect line formation) is labeled with reference D. This average extent D basically corresponds to the average diameter 6 of the laser beam focal line 2b, that is, an average spot diameter in a range of between about 0.1 μm and about 5 μm.

As FIG. 2A shows, the layer 1 (which is transparent to the wavelength λ of laser beam 2) is locally heated due to the induced absorption along the focal line 2b. The induced absorption arises from the nonlinear effects associated with the high intensity (energy density) of the laser beam within focal line 2b. FIG. 2B illustrates that the heated layer 1 will eventually expand so that a corresponding induced tension leads to micro-crack formation, with the tension being the highest at surface 1a.

Representative optical assemblies 6, which can be applied to generate the focal line 2b, as well as a representative optical setup, in which these optical assemblies can be applied, are described below. All assemblies or setups are based on the description above so that identical references are used for identical components or features or those which are equal in their function. Therefore only the differences are described below.

To ensure high quality (regarding breaking strength, geometric precision, roughness and avoidance of re-machining requirements) of the surface of separation after cracking along the contour defined by the series of perforations, the individual focal lines used to form the perforations that define the contour of cracking should be generated using the optical assembly described below (hereinafter, the optical assembly is alternatively also referred to as laser optics). The roughness of the separated surface is determined primarily by the spot size or the spot diameter of the focal line. Roughness of a surface can be characterized, for example, by an Ra surface roughness parameter defined by the ASME B46.1 standard. As described in ASME B46.1, Ra is the arithmetic average of the absolute values of the surface profile height deviations from the mean line, recorded within the evaluation length. In alternative terms, Ra is the average of a set of absolute height deviations of individual features (peaks and valleys) of the surface relative to the mean.

In order to achieve a small spot size of, for example, 0.5 μm to 2 μm for a given wavelength λ of the laser 3 that interacts with the material of layer 1, certain requirements must usually be imposed on the numerical aperture of laser optics 6. These requirements are met by laser optics 6 described below. In order to achieve the required numerical aperture, the optics must, on the one hand, dispose of the required opening for a given focal length, according to the known Abbé formulae (N.A.=n sin (theta), n: refractive index of the material to be processed, theta: half the aperture angle; and theta=arctan(D_{L}/2f); D_{L}: aperture diameter, f: focal length). On the other hand, the laser beam must illuminate the optics up to the required aperture, which is typically achieved by means of beam widening using widening telescopes between the laser and focusing optics.

The spot size should not vary too strongly for the purpose of a uniform interaction along the focal line. This can, for example, be ensured (see the embodiment below) by illuminating the focusing optics only in a small, circular area so that the beam opening and thus the percentage of the numerical aperture only vary slightly.

According to FIG. 3A (section perpendicular to the substrate plane at the level of the central beam in the laser beam bundle of laser radiation 2; here, too, laser beam 2 is perpendicularly incident to the layer 1 (before entering optical assembly 6), i.e. incidence angle θ is 0° so that the focal line 2b or the section of the induced absorption 2c is parallel to the substrate normal), the laser radiation 2a emitted by laser 3 is first directed onto a circular aperture 8 which is completely opaque to the laser radiation used. Aperture 8 is oriented perpendicular to the longitudinal beam axis and is centered on the central beam of the depicted beam bundle 2a. The diameter of aperture 8 is selected in such a way that the beam bundles near the center of beam bundle 2a or the central beam (here labeled with 2aZ) hit the aperture and are completely blocked by it. Only the beams in the outer perimeter range of beam bundle 2a (marginal rays, here labeled with 2aR) are not blocked due to the reduced aperture size compared to the beam diameter, but pass aperture 8 laterally and hit the marginal areas of the focusing optic elements of the optical assembly 6, which, in this embodiment, is designed as a spherically cut, bi-convex lens 7.

Lens 7 is centered on the central beam and is designed as a non-corrected, bi-convex focusing lens in the form of a common, spherically cut lens. The spherical aberration of such a lens may be advantageous. As an alternative, aspheres or multi-lens systems deviating from ideally corrected systems, which do not form an ideal focal point but a distinct, elongated focal line of a defined length, can also be used (i.e., lenses or systems which do not have a single focal point). The zones of the lens thus focus along a focal line 2b, subject to the distance from the lens center. The diameter of aperture 8 across the beam direction is approximately 90% of the diameter of the beam bundle (defined by the distance required for the intensity of the beam to decrease to 1/e² of the peak intensity) and approximately 75% of the diameter of the lens 7 of the optical assembly 6. The focal line 2b of a non-aberration-corrected spherical lens 7 generated by blocking out the beam bundles in the center is thus used. FIG. 3A shows the section in one plane through the central beam, the complete three-dimensional bundle can be seen when the depicted beams are rotated around the focal line 2b.

One potential disadvantage of this type of a focal line formed by lens 7 and the system shown in FIG. 3A is that the conditions (spot size, laser intensity) may vary along the focal line (and thus along the desired depth in the material) and therefore the desired type of interaction (no melting, induced absorption, thermal-plastic deformation up to crack formation) may possibly occur only in selected portions of the focal line. This means in turn that possibly only a part of the incident laser light is absorbed by the material to be processed in the desired way. In this way, the efficiency of the process (required average laser power for the desired separation speed) may be impaired, and the laser light may also be transmitted into undesired regions (parts or layers adherent to the substrate or the substrate holding fixture) and interact with them in an undesirable way (e.g. heating, diffusion, absorption, unwanted modification).

FIG. 3B-1-4 show (not only for the optical assembly in FIG. 3A, but also for any other applicable optical assembly 6) that the position of laser beam focal line 2b can be controlled by suitably positioning and/or aligning the optical assembly 6 relative to layer 1 as well as by suitably selecting the parameters of the optical assembly 6. As FIG. 3B-1 illustrates, the length l of the focal line 2b can be adjusted in such a way that it exceeds the layer thickness d (here by factor 2). If layer 1 is placed (viewed in longitudinal beam direction) centrally to focal line 2b, a section of induced absorption 2c is generated over the entire substrate thickness.

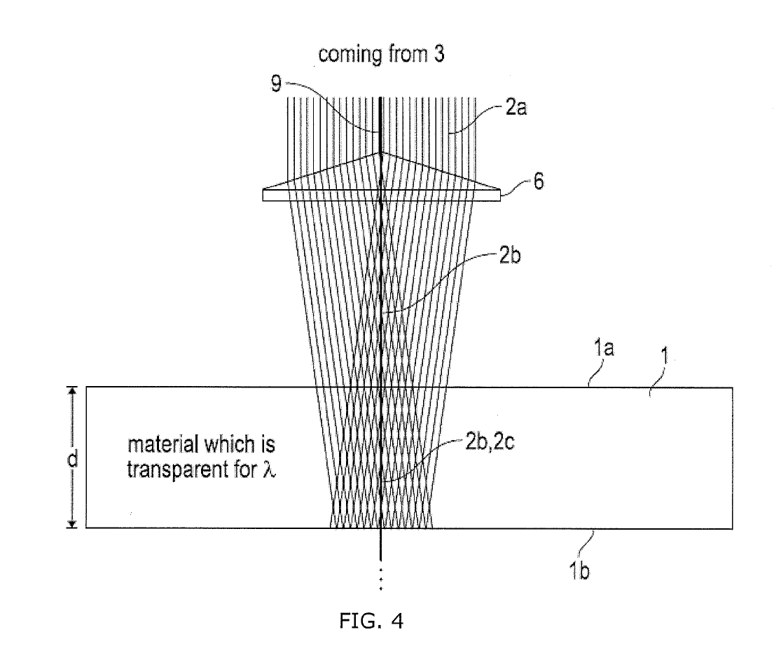

In the case shown in FIG. 3B-2, a focal line 2b of length l is generated which corresponds more or less to the layer thickness d. Since layer 1 is positioned relative to line 2b in such a way that line 2b starts at a point outside the material to be processed, the length L of the section of induced absorption 2c (which extends here from the substrate surface to a defined substrate depth, but not to the reverse surface 1b) is smaller than the length l of focal line 2b. FIG. 3B-3 shows the case in which the substrate 1 (viewed along the beam direction) is positioned above the starting point of focal line 2b so that, as in FIG. 3B-2, the length l of line 2b is greater than the length L of the section of induced absorption 2c in layer 1. The focal line thus starts within the layer 1 and extends beyond the reverse (remote) surface 1b. FIG. 3B-4 shows the case in which the focal line length l is smaller than the layer thickness d so that—in the case of a central positioning of the substrate relative to the focal line viewed in the direction of incidence—the focal line starts near the surface 1a within the layer 1 and ends near the surface 1b within the layer 1 (e.g. 1=0.75·d). The laser beam focal line 2b can have a length l in a range of between about 0.1 mm and about 100 mm or in a range of between about 0.1 mm and about 10 mm, or in a range of between about 0.1 mm and about 1 mm, for example. Various embodiments can be configured to have length l of about 0.1 mm, 0.2 mm, 0.3 mm, 0.4 mm, 0.5 mm, 0.7 mm, 1 mm, 2 mm, 3 mm or 5 mm, for example.

It is particularly advantageous to position the focal line 2b in such a way that at least one of surfaces 1a, 1b is covered by the focal line, so that the section of induced nonlinear absorption 2c starts at least on one surface of the layer or material to be processed. In this way it is possible to achieve virtually ideal cuts while avoiding ablation, feathering and particulation at the surface.

FIG. 4 depicts another applicable optical assembly 6. The basic construction follows the one described in FIG. 3A so that only the differences are described below. The depicted optical assembly is based the use of optics with a non-spherical free surface in order to generate the focal line 2b, which is shaped in such a way that a focal line of defined length l is formed. For this purpose, aspheres can be used as optic elements of the optical assembly 6. In FIG. 4, for example, a so-called conical prism, also often referred to as axicon, is used. An axicon is a special, conically cut lens which forms a spot source on a line along the optical axis (or transforms a laser beam into a ring). The layout of such an axicon is principally known to those of skill in the art; the cone angle in the example is 10°. The apex of the axicon labeled here with reference 9 is directed towards the incidence direction and centered on the beam center. Since the focal line 2b produced by the axicon 9 starts within its interior, layer 1 (here aligned perpendicularly to the main beam axis) can be positioned in the beam path directly behind axicon 9. As FIG. 4 shows, it is also possible to shift layer 1 along the beam direction due to the optical characteristics of the axicon while remaining within the range of focal line 2b. The section of induced absorption 2c in the material of layer 1 therefore extends over the entire depth d.

However, the depicted layout is subject to the following restrictions: Since the region of focal line 2b formed by axicon 9 begins within the axicon 9, a significant part of the laser energy is not focused into the section of induced absorption 2c of focal line 2b, which is located within the material, in the situation where there is a separation between axicon 9 and the material to be processed. Furthermore, length l of focal line 2b is related to the beam diameter through the refractive indices and cone angles of axicon 9. This is why, in the case of relatively thin materials (several millimeters), the total focal line is much longer than the thickness of the material to be processed, having the effect that much of the laser energy is not focused into the material.

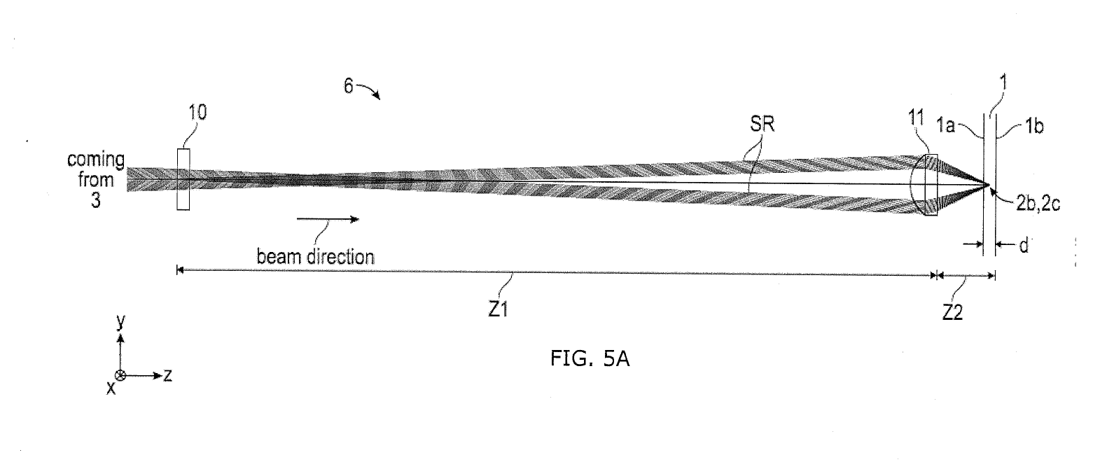

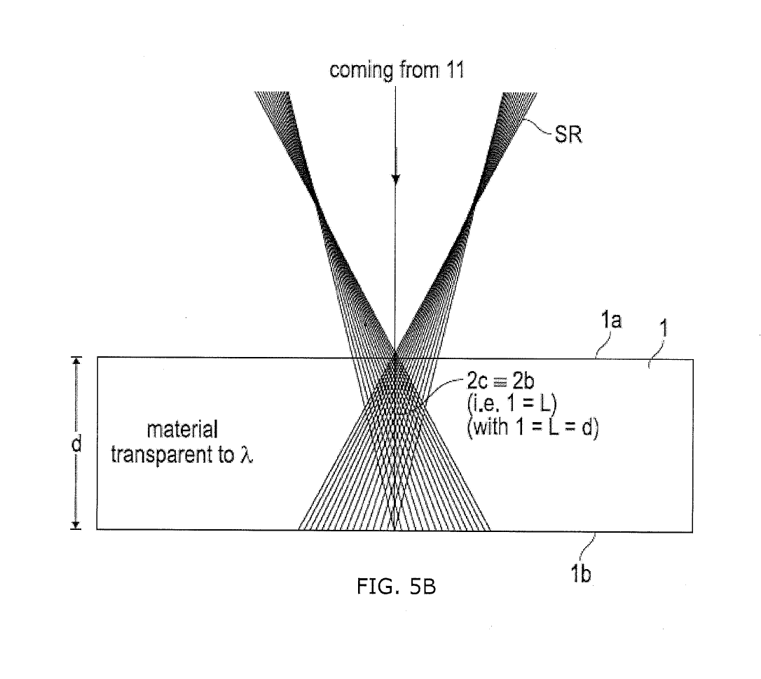

For this reason, it may be desirable to use an optical assembly 6 that includes both an axicon and a focusing lens. FIG. 5A depicts such an optical assembly 6 in which a first optical element (viewed along the beam direction) with a non-spherical free surface designed to form a laser beam focal line 2b is positioned in the beam path of laser 3. In the case shown in FIG. 5A, this first optical element is an axicon 10 with a cone angle of 5°, which is positioned perpendicularly to the beam direction and centered on laser beam 3. The apex of the axicon is oriented towards the beam direction. A second, focusing optical element, here the plano-convex lens 11 (the curvature of which is oriented towards the axicon), is positioned in the beam direction at a distance Z1 from the axicon 10. The distance Z1, in this case approximately 300 mm, is selected in such a way that the laser radiation formed by axicon 10 is circularly incident on the outer radial portion of lens 11. Lens 11 focuses the circular radiation on the output side at a distance Z2, in this case approximately 20 mm from lens 11, on a focal line 2b of a defined length, in this case 1.5 mm. The effective focal length of lens 11 is 25 mm in this embodiment. The circular transformation of the laser beam by axicon 10 is labeled with the reference SR.

FIG. 5B depicts the formation of the focal line 2b or the induced absorption 2c in the material of layer 1 according to FIG. 5A in detail. The optical characteristics of both elements 10, 11 as well as the positioning of them is selected in such a way that the length l of the focal line 2b in beam direction is exactly identical with the thickness d of layer 1. Consequently, an exact positioning of layer 1 along the beam direction is required in order to position the focal line 2b exactly between the two surfaces 1a and 1b of layer 1, as shown in FIG. 5B.

It is therefore advantageous if the focal line is formed at a certain distance from the laser optics, and if the greater part of the laser radiation is focused up to a desired end of the focal line. As described, this can be achieved by illuminating a primarily focusing element 11 (lens) only circularly (annularly) over a particular outer radial region, which, on the one hand, serves to realize the required numerical aperture and thus the required spot size, and, on the other hand, however, the circle of diffusion diminishes in intensity after the required focal line 2b over a very short distance in the center of the spot, as a basically circular spot is formed. In this way, the formation of defect lines is stopped within a short distance in the required substrate depth. A combination of axicon 10 and focusing lens 11 meets this requirement. The axicon acts in two different ways: due to the axicon 10, a usually round laser spot is sent to the focusing lens 11 in the form of a ring, and the asphericity of axicon 10 has the effect that a focal line is formed beyond the focal plane of the lens instead of a focal point in the focal plane. The length l of focal line 2b can be adjusted via the beam diameter on the axicon. The numerical aperture along the focal line, on the other hand, can be adjusted via the distance Z1 (axicon-lens separation) and via the cone angle of the axicon. In this way, the entire laser energy can be concentrated in the focal line.

If the formation of the defect line is intended to continue to the back side of the layer or material to be processed, the circular (annular) illumination still has the advantage that (1) the laser power is used optimally in the sense that most of the laser light remains concentrated in the required length of the focal line, and (2) it is possible to achieve a uniform spot size along the focal line—and thus a uniform separation process along the perforations produced by the focal lines—due to the circularly illuminated zone in conjunction with the desired aberration set by means of the other optical functions.

Instead of the plano-convex lens depicted in FIG. 5A, it is also possible to use a focusing meniscus lens or another higher corrected focusing lens (asphere, multi-lens system).

In order to generate very short focal lines 2b using the combination of an axicon and a lens depicted in FIG. 5A, it would be necessary to select a very small beam diameter of the laser beam incident on the axicon. This has the practical disadvantage that the centering of the beam onto the apex of the axicon must be very precise and that the result is very sensitive to directional variations of the laser (beam drift stability). Furthermore, a tightly collimated laser beam is very divergent, i.e. due to the light deflection the beam bundle becomes blurred over short distances.

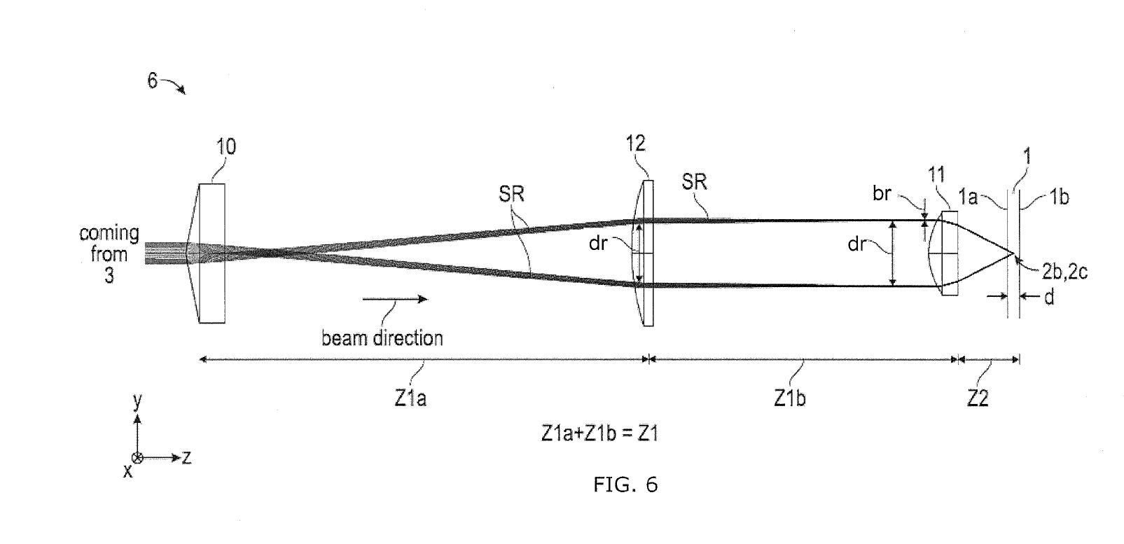

As shown in FIG. 6, both effects can be avoided by including another lens, a collimating lens 12 in the optical assembly 6. The additional positive lens 12 serves to adjust the circular illumination of focusing lens 11 very tightly. The focal length f of collimating lens 12 is selected in such a way that the desired circle diameter dr results from distance Z1a from the axicon to the collimating lens 12, which is equal to f. The desired width br of the ring can be adjusted via the distance Z1b (collimating lens 12 to focusing lens 11). As a matter of pure geometry, the small width of the circular illumination leads to a short focal line. A minimum can be achieved at distance f.

The optical assembly 6 depicted in FIG. 6 is thus based on the one depicted in FIG. 5A so that only the differences are described below. The collimating lens 12, here also designed as a plano-convex lens (with its curvature towards the beam direction) is additionally placed centrally in the beam path between axicon 10 (with its apex towards the beam direction), on the one side, and the plano-convex lens 11, on the other side. The distance of collimating lens 12 from axicon 10 is referred to as Z1a, the distance of focusing lens 11 from collimating lens 12 as Z1b, and the distance of the focal line 2b from the focusing lens 11 as Z2 (always viewed in beam direction). As shown in FIG. 6, the circular radiation SR formed by axicon 10, which is incident divergently and under the circle diameter dr on the collimating lens 12, is adjusted to the required circle width br along the distance Z1b for an at least approximately constant circle diameter dr at the focusing lens 11. In the case shown, a very short focal line 2b is intended to be generated so that the circle width br of approximately 4 mm at lens 12 is reduced to approximately 0.5 mm at lens 11 due to the focusing properties of lens 12 (circle diameter dr is 22 mm in the example).

In the depicted example it is possible to achieve a length of the focal line 1 of less than 0.5 mm using a typical laser beam diameter of 2 mm, a focusing lens 11 with a focal length f=25 mm, a collimating lens with a focal length f′=150 mm, and choosing distances Z1a=Z1b=140 mm and Z2=15 mm.

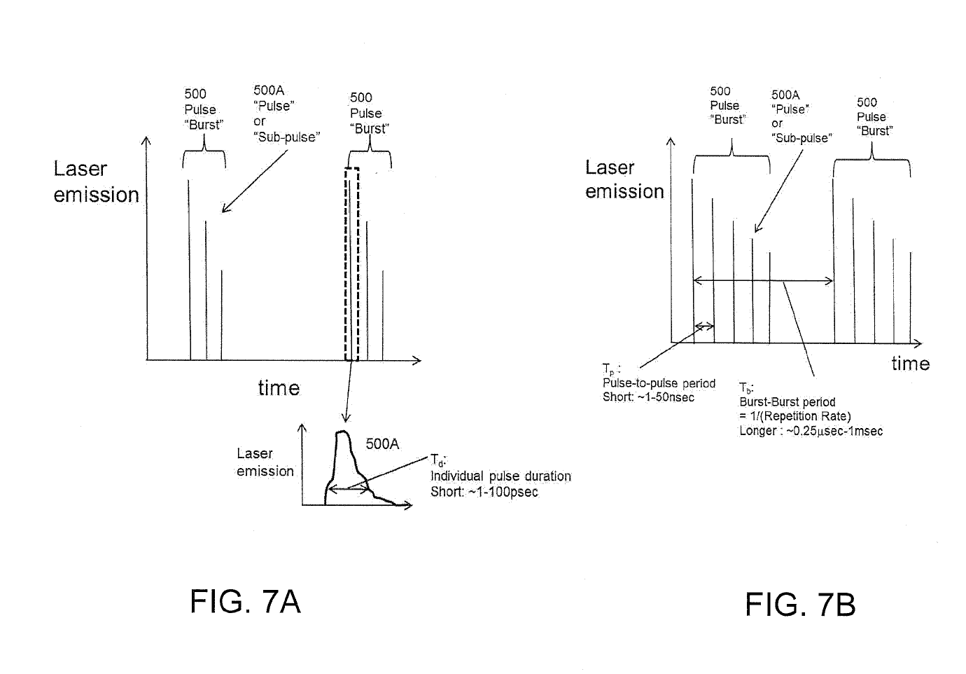

More specifically, as illustrated in FIGS. 7A and 7B, according to certain embodiments described herein, the picosecond laser creates a “burst” 500 of pulses 500A, sometimes also called a “burst pulse”. Bursting is a type of laser operation where the emission of pulses is not in a uniform and steady stream but rather in tight clusters of pulses. Each “burst” 500 may contain multiple pulses 500A (such as 2 pulses, 3 pulses, 4 pulses, 5 pulses, 10, 15, 20, or more) of very short duration T_{d} up to 100 psec (for example, 0.1 psec, 5 psec, 10 psec, 15 psec, 18 psec, 20 psec, 22 psec, 25 psec, 30 psec, 50 psec, 75 psec, or therebetween). The pulse duration is generally in a range from about 1 psec to about 1000 psec, or in a range from about 1 psec to about 100 psec, or in a range from about 2 psec to about 50 psec, or in a range from about 5 psec to about 20 psec. These individual pulses 500A within a single burst 500 can also be termed “sub-pulses,” which simply denotes the fact that they occur within a single burst of pulses. The energy or intensity of each laser pulse 500A within the burst may not be equal to that of other pulses within the burst, and the intensity distribution of the multiple pulses within a burst 500 may follow an exponential decay in time governed by the laser design. Preferably, each pulse 500A within the burst 500 of the exemplary embodiments described herein are separated in time from the subsequent pulse in the burst by a duration Tₚ from 1 nsec to 50 nsec (e.g. 10-50 nsec, or 10-40 nsec, or 10-30 nsec, with the time often governed by the laser cavity design. For a given laser, the time separation Tₚ between each pulses (pulse-to-pulse separation) within a burst 500 is relatively uniform (±10%). For example, in some embodiments, each pulse is separated in time from the subsequent pulse by approximately 20 nsec (50 MHz pulse repetition frequency). For example, for a laser that produces pulse-to-pulse separation Tₚ of about 20 nsec, the pulse-to-pulse separation Tₚ within a burst is maintained within about ±10%, or is about ±2 nsec. The time between each “burst” (i.e., time separation T_{b} between bursts) will be much longer (e.g., 0.25<T_{b}<1000 microseconds, for example 1-10 microseconds, or 3-8 microseconds,) For example in some of the exemplary embodiments of the laser described herein it is around 5 microseconds for a laser repetition rate or frequency of about 200 kHz. The laser repetition rate is also referred to as burst repetition frequency or burst repetition rate herein, and is defined as the time between the first pulse in a burst to the first pulse in the subsequent burst. In other embodiments, the burst repetition frequency is in a range of between about 1 kHz and about 4 MHz, or in a range between about 1 kHz and about 2 MHz, or in a range of between about 1 kHz and about 650 kHz, or in a range of between about 10 kHz and about 650 kHz. The time T_{b} between the first pulse in each burst to the first pulse in the subsequent burst may be 0.25 microsecond (4 MHz burst repetition rate) to 1000 microseconds (1 kHz burst repetition rate), for example 0.5 microseconds (2 MHz burst repetition rate) to 40 microseconds (25 kHz burst repetition rate), or 2 microseconds (500 kHz burst repetition rate) to 20 microseconds (50 kHz burst repetition rate). The exact timings, pulse durations, and repetition rates can vary depending on the laser design and user-controllable operating parameters. Short pulses (T_{d}<20 psec and preferably T_{d}≦15 psec) of high intensity have been shown to work well.

The required energy to modify the material can be described in terms of the burst energy—the energy contained within a burst (each burst 500 contains a series of pulses 500A), or in terms of the energy contained within a single laser pulse (many of which may comprise a burst). For these applications, the energy per burst (per millimeter of the material to be cut) can be from 10-2500 μJ, or from 20-1500 μJ, or from 25-750 μJ, or from 40-2500 μJ, or from 100-1500 μJ, or from 200-1250 μJ, or from 250-1500 μJ, or from 250-750 μJ. The energy of an individual pulse within the burst will be less, and the exact individual laser pulse energy will depend on the number of pulses 500A within the burst 500 and the rate of decay (e.g, exponential decay rate) of the laser pulses with time as shown in FIGS. 7A and 7B. For example, for a constant energy/burst, if a pulse burst contains 10 individual laser pulses 500A, then each individual laser pulse 500A will contain less energy than if the same burst pulse 500 had only 2 individual laser pulses.

The use of lasers capable of generating such pulse bursts is advantageous for cutting or modifying transparent materials, for example glass. In contrast with the use of single pulses spaced apart in time by the repetition rate of a single-pulsed laser, the use of a burst pulse sequence that spreads the laser energy over a rapid sequence of pulses within burst 500 allows access to larger timescales of high intensity interaction with the material than is possible with single-pulse lasers. While a single-pulse can be expanded in time, conservation of energy dictates that as this is done, the intensity within the pulse must drop as roughly one over the pulse width. Hence if a 10 psec single pulse is expanded to a 10 nsec pulse, the intensity drops by roughly three orders of magnitude. Such a reduction can reduce the optical intensity to the point where non-linear absorption is no longer significant and the light-material interaction is no longer strong enough to allow for cutting. In contrast, with a burst pulse laser, the intensity during each pulse or sub-pulse 500A within the burst 500 can remain very high—for example three pulses 500A with pulse duration T_{d} 10 psec that are spaced apart in time by a separation Tₚ of approximately 10 nsec still allows the intensity within each pulse to be approximately three times higher than that of a single 10 psec pulse, while the laser is allowed to interact with the material over a timescale that is three orders of magnitude larger. This adjustment of multiple pulses 500A within a burst thus allows manipulation of timescale of the laser-material interaction in ways that can facilitate greater or lesser light interaction with a pre-existing plasma plume, greater or lesser light-material interaction with atoms and molecules that have been pre-excited by an initial or previous laser pulse, and greater or lesser heating effects within the material that can promote the controlled growth of defect lines (perforations). The amount of burst energy required to modify the material will depend on the substrate material composition and the length of the line focus used to interact with the substrate. The longer the interaction region, the more the energy is spread out, and the higher the burst energy that will be required.)

A defect line or a hole is formed in the material when a single burst of pulses strikes essentially the same location on the glass. That is, multiple laser pulses within a single burst can produce a single defect line or a hole location in the glass. Of course, if the glass is translated (for example by a constantly moving stage) or the beam is moved relative to the glass, the individual pulses within the burst cannot be at exactly the same spatial location on the glass. However, they are well within 1 μm of one another—i. e., they strike the glass at essentially the same location. For example, they may strike the glass at a spacing sp where 0<sp≦500 nm from one another. For example, when a glass location is hit with a burst of 20 pulses the individual pulses within the burst strike the glass within 250 nm of each other. Thus, in some embodiments 1 nm<sp<250 nm. In in some embodiments 1 nm<sp<100 nm.

In general, the higher the available laser power, the faster the material can be cut with the above process. The process(s) disclosed herein can cut glass at a cutting speed of 0.25 m/sec, or faster. A cut speed (or cutting speed) is the rate the laser beam moves relative to the surface of the substrate material (e.g., glass) while creating multiple defect lines holes. High cut speeds, such as, for example 400 mm/sec, 500 mm/sec, 750 mm/sec, 1 m/sec, 1.2 m/sec, 1.5 m/sec, or 2 m/sec, or even 3.4 m/sec to 4 m/sec are often desired in order to minimize capital investment for manufacturing, and to optimize equipment utilization rate. The laser power is equal to the burst energy multiplied by the burst repetition frequency (rate) of the laser. In general, to cut glass materials at high cutting speeds, the defect lines are typically spaced apart by 1-25 μm, in some embodiments the spacing is preferably 3 μm or larger—for example 3-12 μm, or for example 5-10 μm.

For example, to achieve a linear cutting speed of 300 mm/sec, 3 μm hole pitch corresponds to a pulse burst laser with at least 100 kHz burst repetition rate. For a 600 mm/sec cutting speed, a 3 μm pitch corresponds to a burst-pulsed laser with at least 200 kHz burst repetition rate. A pulse burst laser that produces at least 40 μJ/burst at 200 kHz, and cuts at a 600 mm/s cutting speed needs to have a laser power of at least 8 Watts. Higher cut speeds require accordingly higher laser powers.

For example, a 0.4 m/sec cut speed at 3 μm pitch and 40 μJ/burst would require at least a 5 W laser, a 0.5 m/sec cut speed at 3 μm pitch and 40 μJ/burst would require at least a 6 W laser. Thus, preferably the laser power of the pulse burst picosecond laser is 6 W or higher, more preferably at least 8 W or higher, and even more preferably at least 10 W or higher. For example, in order to achieve a 0.4 m/sec cut speed at 4 μm pitch (defect line spacing, or damage tracks spacing) and 100 μJ/burst, one would require at least a 10 W laser, and to achieve a 0.5 m/sec cut speed at 4 μm pitch and 100 μJ/burst, one would require at least a 12 W laser. For example, a to achieve a cut speed of 1 m/sec at 3 μm pitch and 40 μJ/burst, one would require at least a 13 W laser. Also, for example, 1 m/sec cut speed at 4 μm pitch and 400 μJ/burst would require at least a 100 W laser.

The optimal pitch between defect lines (damage tracks) and the exact burst energy is material dependent and can be determined empirically. However, it should be noted that raising the laser pulse energy or making the damage tracks at a closer pitch are not conditions that always make the substrate material separate better or with improved edge quality. A pitch that is too small (for example <0.1 micron, or in some exemplary embodiments <1 μm, or in other embodiments <2 μm) between defect lines (damage tracks) can sometimes inhibit the formation of nearby subsequent defect lines (damage tracks), and often can inhibit the separation of the material around the perforated contour. An increase in unwanted micro cracking within the glass may also result if the pitch is too small. A pitch that is too long (e.g. >50 μm, and in some glasses >25 μm or even >20 μm) may result in “uncontrolled microcracking”—i.e., where instead of propagating from defect line to defect line along the intended contour, the microcracks propagate along a different path, and cause the glass to crack in a different (undesirable) direction away from the intended contour. This may ultimately lower the strength of the separated part since the residual microcracks constitute flaws that weaken the glass. A burst energy for forming defect lines that is too high (e.g., >2500 μJ/burst, and in some embodiments >500 μJ/burst) can cause “healing” or re-melting of previously formed defect lines, which may inhibit separation of the glass. Accordingly, it is preferred that the burst energy be <2500 μJ/burst, for example, <500 μJ/burst. Also, using a burst energy that is too high can cause formation of microcracks that are extremely large and create structural imperfections that can reduce the edge strength of the part after separation. A burst energy that is too low (e.g. <40 μJ/burst) may result in no appreciable formation of defect lines within the glass, and hence may necessitate especially high separation force or result in a complete inability to separate along the perforated contour.

Typical exemplary cutting rates (speeds) enabled by this process are, for example, 0.25 m/sec and higher. In some embodiments, the cutting rates are at least 300 mm/sec. In some embodiments, the cutting rates are at least 400 mm/sec, for example, 500 mm/sec to 2000 mm/sec, or higher. In some embodiments the picosecond (ps) laser utilizes pulse bursts to produce defect lines with periodicity between 0.5 μm and 13 μm, e.g. between 0.5 and 3 μm. In some embodiments, the pulsed laser has laser power of 10 W-100 W and the material and/or the laser beam are translated relative to one another at a rate of at least 0.25 m/sec; for example, at the rate of 0.25 m/sec to 0.35 m/sec, or 0.4 m/sec to 5 m/sec. Preferably, each pulse burst of the pulsed laser beam has an average laser energy measured at the workpiece greater than 40 μJ per burst per mm thickness of workpiece. Preferably, each pulse burst of the pulsed laser beam has an average laser energy measured at the workpiece greater of less than 2500 μJ per burst per mm thickness of workpiece, and preferably less than about 2000 μJ per burst per mm thickness of workpiece, and in some embodiments less than 1500 μJ per burst per mm thickness of workpiece; for example, not more than 500 μJ per burst per mm thickness of workpiece.

We discovered that much higher (5 to 10 times higher) volumetric pulse energy density (μJ/μm³) is required for perforating alkaline earth boroaluminosilicate glasses with low or no alkali content. This can be achieved, for example, by utilizing pulse burst lasers, preferably with at least 2 pulses per burst and providing volumetric energy densities within the alkaline earth boroaluminosilicate glasses (with low or no alkali) of about 0.05 μJ/μm³ or higher, e.g., at least 0.1 μJ/μm³, for example 0.1-0.5 μJ/μm³.

Accordingly, it is preferable that the laser produces pulse bursts with at least 2 pulses per burst. For example, in some embodiments the pulsed laser has a power of 10 W-150 W (e.g., 10 W-100 W) and produces pulse bursts with at least 2 pulses per burst (e.g., 2-25 pulses per burst). In some embodiments the pulsed laser has a power of 25 W-60 W, and produces pulse bursts with at least 2-25 pulses per burst, and periodicity or distance between the adjacent defect lines produced by the laser bursts is 2-10 μm. In some embodiments, the pulsed laser has a power of 10 W-100 W, produces pulse bursts with at least 2 pulses per burst, and the workpiece and the laser beam are translated relative to one another at a rate of at least 0.25 m/sec. In some embodiments the workpiece and/or the laser beam are translated relative to one another at a rate of at least 0.4 m/sec.

For example, for cutting 0.7 mm thick non-ion exchanged Corning code 2319 or code 2320 Gorilla® glass, it is observed that pitches of 3-7 μm can work well, with pulse burst energies of about 150-250 μJ/burst, and burst pulse numbers that range from 2-15, and preferably with pitches of 3-5 μm and burst pulse numbers (number of pulses per burst) of 2-5.

At 1 m/sec cut speeds, the cutting of Eagle XG® glass typically requires utilization of laser powers of 15-84 W, with 30-45 W often being sufficient. In general, across a variety of glass and other transparent materials, applicants discovered that laser powers between 10 W and 100 W are preferred to achieve cutting speeds from 0.2-1 m/sec, with laser powers of 25-60 W being sufficient (or optimum) for many glasses. For cutting speeds of 0.4 m/sec to 5 m/sec, laser powers should preferably be 10 W-150 W, with burst energy of 40-750 μJ/burst, 2-25 bursts per pulse (depending on the material that is cut), and defect line separation (pitch) of 3 to 15 μm, or 3-10 μm. The use of picosecond pulse burst lasers would be preferable for these cutting speeds because they generate high power and the required number of pulses per burst. Thus, according to some exemplary embodiments, the pulsed laser produces 10 W-100 W of power, for example 25 W to 60 W, and produces pulse bursts at least 2-25 pulses per burst and the distance between the defect lines is 2-15 μm; and the laser beam and/or workpiece are translated relative to one another at a rate of at least 0.25 m/sec, in some embodiments at least 0.4 m/sec, for example 0.5 m/sec to 5 m/sec, or faster.

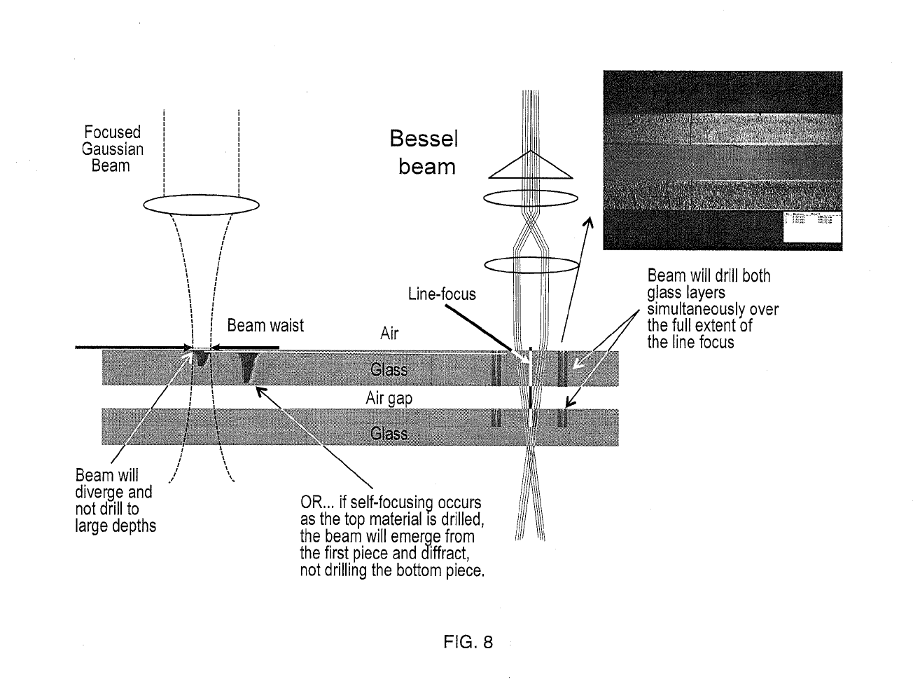

FIG. 8 shows the contrast between a focused Gaussian beam and a Bessel beam incident upon a glass-air-glass composite structure. A focused Gaussian beam will diverge upon entering the first glass layer and will not drill to large depths, or if self-focusing occurs as the glass is drilled, the beam will emerge from the first glass layer and diffract, and will not drill into the second glass layer. Reliance on self-focusing of a Gaussian beam through the Kerr effect (sometimes referred to as “filamentation”) is problematic in structures having an air gap because the power required to induce self focusing in air through the Kerr effect is ˜20 times the power required in glass. In contrast, a Bessel beam will drill both glass layers over the full extent of the line focus. An example of a glass-air-glass composite structure cut with a Bessel beam is shown in the inset photograph in FIG. 8, which shows a side view of the exposed cut edges. The top and bottom glass pieces are 0.4 mm thick Corning Incorporated code 2320 glass, with Central Tension (CT) of 101 MPa. The exemplary air gap between two layers of glass is ˜400 μm. The cut was made with a single pass of the laser at 200 mm/sec, so that the two pieces of glass were cut simultaneously, even though they were separated by ˜400 μm.

In some of the embodiments described herein, the thickness of the air gap is between 50 μm and 5 mm, or between 50 μm and 2 mm, or between 200 μm and 2 mm.

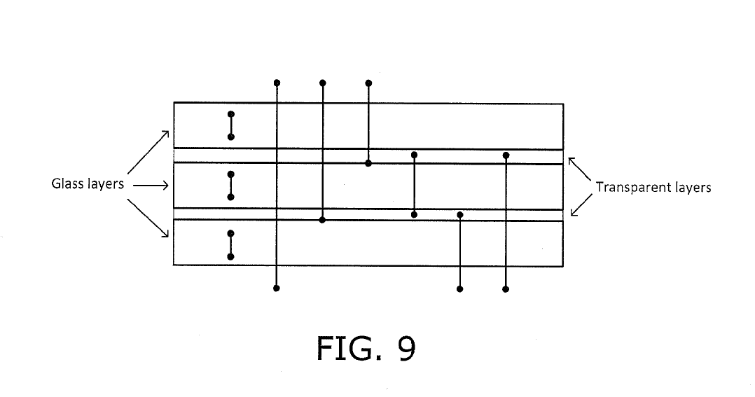

Exemplary beam disruption layers include polyethylene plastic sheeting (e.g., Visqueen, commercially available from British Polythene Industries Limited). Transparent layers, as shown in FIG. 9, include transparent vinyl (e.g., Penstick, commercially available from MOLCO, GmbH). Note that unlike with other focused laser methods, to get the effect of a blocking or stop layer, the exact focus does not need to be precisely controlled, nor does the material of the beam disruption layer need to be particularly durable or expensive. In many applications, one just needs a layer that interferes with the laser light slightly to disrupt the laser light and prevent line focus from occurring. The fact that Visqueen prevents cutting with the picosecond laser and line focus is a perfect example—other focused picosecond laser beams (e.g. Gaussian beams) will most certainly drill right through the Visqueen, and one wishing to avoid drilling right through such a material with other laser methods one would have to very precisely set the laser focus to not be near the Visqueen.

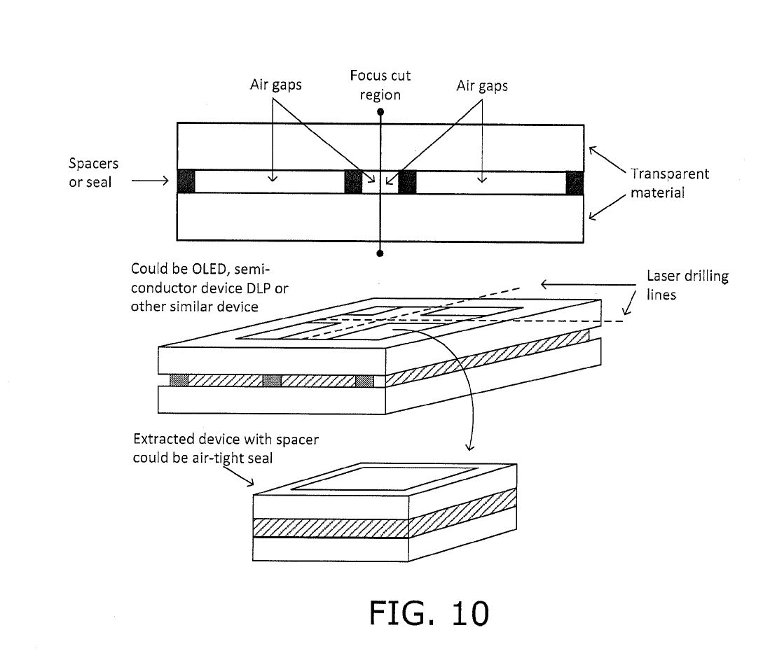

FIG. 10 shows air gap and cutting of encapsulated devices. This line focus process can simultaneously cut through stacked glass sheets, even if a significant macroscopic air gap is present. This is not possible with other laser methods, as illustrated in FIG. 8. Many devices require glass encapsulation, such as OLEDs (organic light emitting diode). Being able to cut through the two glass layers simultaneously is very advantageous for a reliable and efficient device segmentation process. Segmented means one component can be separated from a larger sheet of material that may contain a plurality of other components. Use of a single laser pass to cut the full stack of components means that there is no misalignment between the cut edges of each layer as might occur with a multi-pass method, where a second pass of a laser is never exactly at the location of the first pass. Other components that can be segmented, cut out, or produced by the methods described herein are, for example, OLED (organic light emitting diode) components, DLP (digital light processor) components, an LCD (liquid crystal display) cells, semiconductor device substrates.

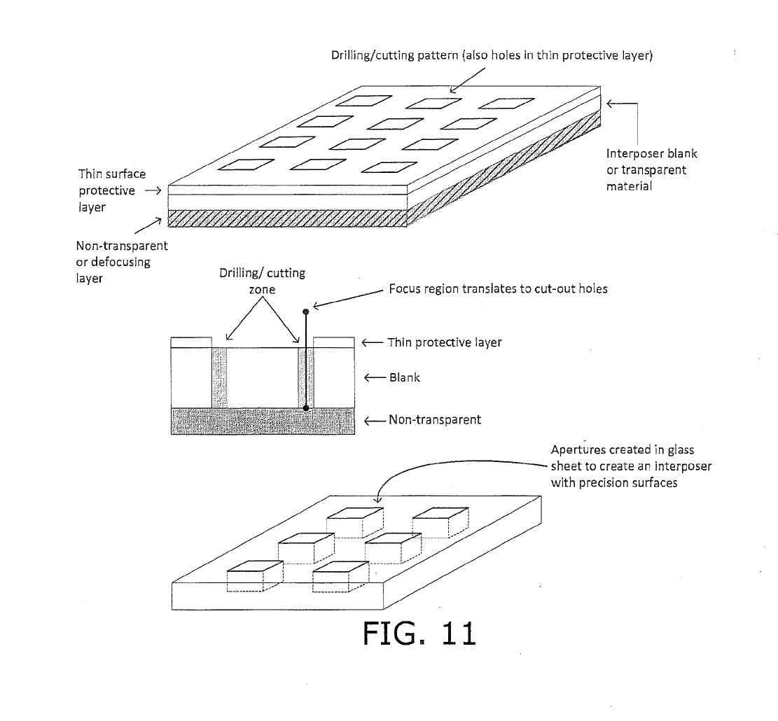

FIG. 11 shows stacking with transparent protective layers to cut multiple sheets while reducing abrasion or contamination. Simultaneously cutting a stack of display glass sheets is very advantageous. A transparent polymer such as vinyl or polyethylene can be placed between the glass sheets. The transparent polymer layers serve as protective layers serve to reduce damage to the glass surfaces which are in close contact with one another. These layers would allow the cutting process to work, but would protect the glass sheets from scratching one another, and would furthermore prevent any cutting debris (albeit it is small with this process) from contaminating the glass surfaces. The protective layers can also be comprised of evaporated dielectric layers deposited on the substrates or glass sheets.

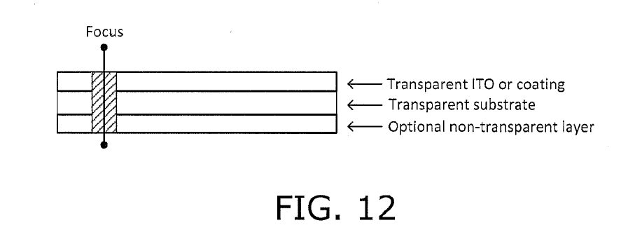

FIG. 12 shows cutting an article such as electrochromic glass (labeled “Transparent substrate”) coated with transparent electrically conductive layers (e.g. ITO). Cutting glass that already has transparent conducting layers such as indium tin oxide (ITO) is of high value for electrochromic glass applications and also touch panel devices. This laser process can cut through such layers with minimal damage to the transparent electrically conductive layer and very little debris generation. The extremely small size of the perforated holes (<5 um) means that very little of the ITO will be affected by the cutting process, whereas other cutting methods are going to generate far more surface damage and debris.

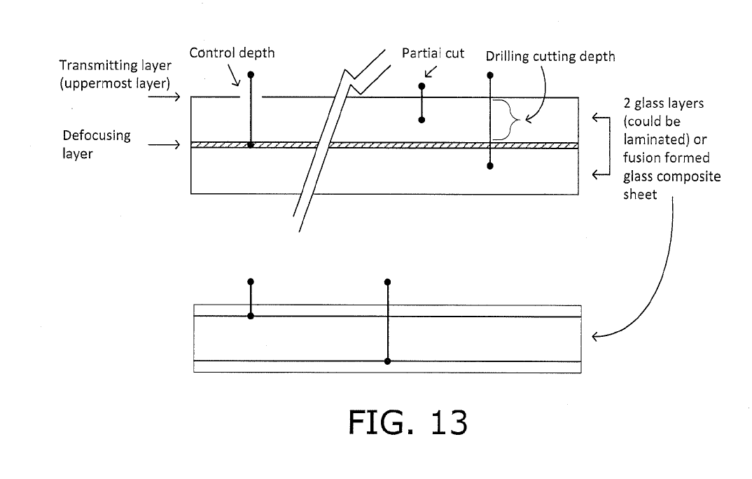

FIG. 13 shows precision cutting of some layers in a stack while not damaging others, as also shown in FIG. 1, extending the concept to multiple layers (i.e., more than two layers). In the embodiment of FIG. 13, the beam disruption element is a defocusing layer.

Embodiment methods have the advantage that substantially transparent materials such as glass, plastic, and rubber can be perforated and cut. The perforation can be through multiple laminate layers or selected layers of a laminate workpiece. Very unique product shapes and features can be produced, and embodiments can even be used to cut a formed 3D shape, with the laser beam oriented at a normal to a 3D surface of the laminate workpiece to perforate all layers, for example. Selected layers can also be perforated and/or weakened to allow for controlled breakage, such as for automotive windshields or other safety glass applications. Laminate layers of glass, plastic, and/or rubber with layer thicknesses of 0.1 mm to 1 mm, for example, can be cut at high speed for manufacturing, with very high accuracy and with very good edge quality. The disclosed laser processes can even eliminate a need for any edge finishing, which has significant cost advantages.

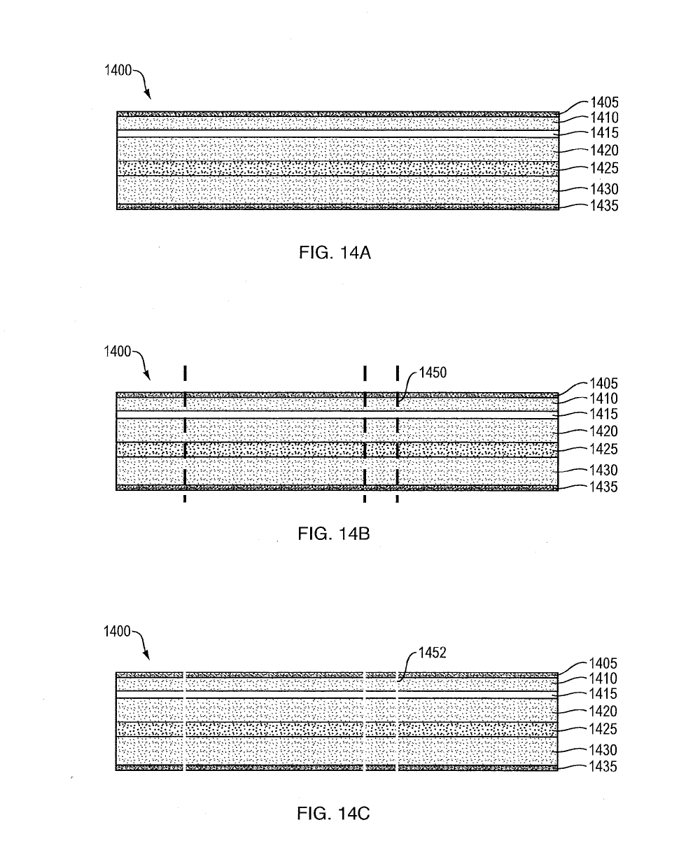

FIG. 14A is a side-view illustration of an example laminate stack including plastic film outer layers with glass or plastic inner layers. Laminate stack 1400 includes layers 1410, 1415, 1420, 1425, and 1430 between plastic film 1405 and plastic film 1435. Layers 1410, 1415, 1420, 1425, and 1430 may be glass or plastic and may be the same or different composition. Plastic films 1405 and 1435 have typical thicknesses in the range from 0.01 mm-0.10 mm. Layers 1410, 1415, 1420, 1425, and 1430 have typical thicknesses in the range from 0.05 mm-1.5 mm. The total thickness of laminate stack 1400 is typically in the range from 1.0 mm-4.0 mm. The laminate can be fused together, joined with adhesive, or even have air or vacuum gaps between adjacent layers. If all the layers are substantially transparent and lack significant defects that could disrupt the laser beam, laser perforations can be made through all or part of the laminate.

FIG. 14B illustrates laser perforations 1450 made through all layers of the laminate illustrated in FIG. 14A using disclosed laser methods to cut the laminate. In some embodiments, the laminate has a 3D surface, and the laser is positioned at an angle that accommodates the laminate shape and allows the laser beam to perforate the laminate at a normal to the 3D surface of the laminate, for example.

FIG. 14C illustrates defect lines 1452 that result from the laser perforations 1450. A series of adjacent defect lines can leave the laminate weakened and prepared for separation along an edge or contour defined by the series adjacent defect lines.

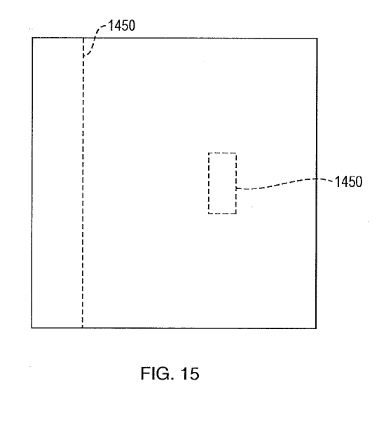

FIG. 15 is a top-view illustration of the laminate shown in FIGS. 14A-C. FIG. 15 shows that the laser perforations are formed to facilitate removal of both one entire edge of the laminate and a rectangular section of the laminate. This cutting can be done with a series of adjacent laser perforations as shown. In FIG. 15, the series of adjacent laser perforations are in straight lines oriented vertically and horizontally. However, in other cases, the adjacent perforations are along a curved contour, for example. Furthermore, holes, slots, openings, depressions, and any shape can be produced. The glass or plastic rectangle shown in FIG. 15 (or other shape in other cases) can be removed by mechanically pushing it through the material, as done in a punch and die method, for example. The glass or plastic can also be removed using other methods such as using a vacuum suction cup, for example.

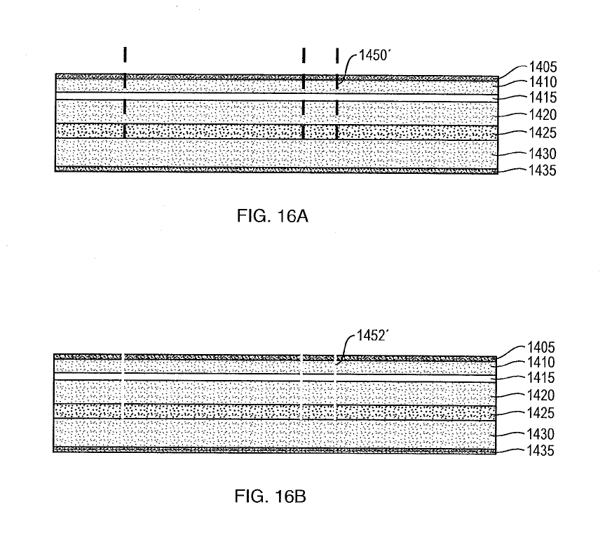

FIG. 16A is a side-view illustration of a laminate similar to the one shown in FIGS. 14A-C. However, laser perforations 1450′ extend only through some layers of the laminate. The depth of the perforations can be chosen to allow any number of layers to be cut and removed, leaving the remaining layers in place. Thus, holes, slots, openings, depressions, and other features of any shape can be cut. This method of cutting can result in cutting and removing selected areas, creating a laminate shape with one or more 3D surfaces.

FIG. 16B shows defect lines 1452′ corresponding to the laser perforations 1450′ extending only to a specific depth in the laminate.

The relevant teachings of all patents, published applications and references cited herein are incorporated by reference in their entirety.

While exemplary embodiments have been described herein, it will be understood by those skilled in the art that various changes in form and details may be made therein without departing from the scope encompassed by the appended claims.

What is claimed is:

1. A method of laser processing comprising:
forming a laser beam focal line in a workpiece, the laser beam focal line being formed from a pulsed laser beam,
the workpiece comprising: a first layer, a second layer, and a beam disruption element located between the first and second layers; and
the laser beam focal line generating an induced absorption within the first layer, the induced absorption producing a defect line along the laser beam focal line within the first layer.

2. The method of claim 1, further including translating the workpiece and the laser beam relative to each other along a contour, thereby forming a plurality of defect lines along the contour within the first layer, the spacing between adjacent defect lines being between 0.5 μm and 20 μm.

3. The method of claim 2, wherein the contour is a closed contour.

4. The method of claim 2, further comprising fracturing the workpiece along the contour.

5. The method of claim 4, wherein the fracturing separates a part from the workpiece.

6. The method of claim 1, wherein the beam disruption element is a beam disruption layer.

7. The method of claim 6, wherein the beam disruption layer is a reflective material.

8. The method of claim 1, wherein the beam disruption layer is a defocusing layer.

9. The method of claim 8, wherein the defocusing layer is a translucent material.

10. The method of claim 1, wherein the second layer is a carrier layer.

11. The method of claim 1, wherein the first layer comprises a glass sheet.

12. The method of claim 7, wherein the extent of the defect line produced through the glass sheet coincides with the length of the laser beam focal line in the glass sheet.

13. The method of claim 1, wherein the first and second layers comprise glass.

14. The method of claim 1, wherein the laser beam has a pulse duration in a range of between greater than about 1 picosecond and less than about 100 picoseconds.

15. The method of claim 14, wherein the pulse duration is in a range of between greater than about 5 picoseconds and less than about 20 picoseconds.

16. The method of claim 1, wherein the laser beam has a repetition rate in a range of between about 1 kHz and 2 MHz.

17. The method of claim 12, wherein the repetition rate is in a range of between about 10 kHz and 650 kHz.

18. The method of claim 1, wherein the pulsed laser beam provides bursts of two or more pulses, the bursts having energy greater than 40 μJ per mm thickness in the first layer.

19. The method of claim 1, wherein the laser beam provides pulses in bursts of at least two pulses separated by a duration in a range of between about 1 nsec and about 50 nsec, and the repetition frequency of the bursts is in a range of between about 1 kHz and about 650 kHz.

20. The method of claim 19, wherein the pulses of the bursts are separated by a duration of 10-30 nsec.

21. The method of claim 1, wherein the pulsed laser beam has a wavelength selected such that the first layer is substantially transparent at this wavelength.

22. The method of claim 1, wherein the defect line has a length in a range of between about 0.1 mm and about 100 mm.

23. The method of claim 22, wherein the defect line has a length in a range of between about 0.1 mm and about 1 mm.

24. The method of claim 1, wherein the defect line has an average diameter in a range of between about 0.1 μm and about 5 μm.

25. A method of laser processing comprising:
forming a laser beam focal line in a workpiece, the laser beam focal line being formed from a pulsed laser beam,
the workpiece comprising a glass layer and a transparent electrically conductive layer, the laser beam focal line generating an induced absorption within the workpiece, the induced absorption producing a defect line along the laser beam focal line through the transparent electrically conductive layer and into the glass layer.

26. The method of claim 25, further including translating the workpiece and the laser beam relative to each other, thereby forming a plurality of defect lines within the workpiece, wherein the spacing between adjacent defect lines is between 0. 5 μm and 20 μm.

27. The method of claim 25, wherein the transparent electrically conductive layer comprises indium tin oxide.

28. A method of laser processing comprising:
forming a laser beam focal line in a workpiece, the laser beam focal line being formed from a pulsed laser beam, the workpiece comprising a plurality of glass layers, the workpiece including a transparent protective layer between each of the glass layers, the laser beam focal line generating an induced absorption within the workpiece, the induced absorption producing a defect line along the laser beam focal line within the workpiece.

29. The method of claim 28, further including translating the workpiece and the laser beam relative to each other, thereby forming a plurality of defect lines within the workpiece, wherein the spacing between adjacent defect lines is between 0.5 μm and 20 μm.

30. The method of claim 28, wherein the transparent protective layer comprises an epoxy.

31. The method of claim 28, wherein the transparent protective layer comprises vinyl.

32. The method of claim 28, wherein the transparent protective layer comprises polyethylene.

33. The method of claim 28, wherein the extent of the defect line produced through the workpiece coincides with the length of the laser beam focal line.

34. A method of laser processing comprising:
forming a laser beam focal line in a workpiece, the laser beam focal line being formed from a pulsed laser beam,
the workpiece comprising a plurality of glass layers, the workpiece including an air gap between each of the glass layers, the laser beam focal line generating an induced absorption within the workpiece, the induced absorption producing a defect line along the laser beam focal line within the workpiece.

35. The method of claim 34, further including translating the workpiece and the laser beam relative to each other, thereby forming a plurality of defect lines within the workpiece, wherein the spacing between adjacent defect lines is between 0. 5 μm and 20 μm.

36. The method of claim 34, wherein the air gap is provided by epoxy or glass frits adhered between the glass layers.

37. The method of claim 34, wherein the air gap has a thickness between 50 μm and 5 mm.

38. The method of claim 34, wherein the air gap has a thickness between 50 μm and 2 mm.

39. The method of claim 34, wherein the workpiece is any of: an OLED component, a DLP component, a LCD cell(s), or a semiconductor device.

40. The method of claim 34, wherein the extent of the defect line produced through the workpiece coincides with the length of the laser beam focal line.

41. A method of laser processing comprising:
forming a laser beam focal line in a workpiece, the laser beam focal line being formed from a pulsed laser beam,
the workpiece having a glass layer, the laser beam focal line generating an induced absorption within the glass layer, the induced absorption producing a defect line along the laser beam focal line within the glass layer;
translating the workpiece and the laser beam relative to each other along a contour, thereby forming a plurality of defect lines in the glass layer along the contour; and
applying an acid etch process, the acid etch process separating the glass layer along the contour.

42. The method of claim 41, wherein the contour is an internal contour formed within the glass layer.

43. A method of laser processing comprising:
forming a laser beam focal line in a workpiece, the laser beam focal line being formed from a pulsed laser beam,
the workpiece having a glass layer, the laser beam focal line generating an induced absorption within the workpiece, the induced absorption producing a defect line along the laser beam focal line within the workpiece;
translating the workpiece and the laser beam relative to each other along a closed contour, thereby forming a plurality of defect lines along the closed contour; and
applying an acid etch process, the acid etch process facilitating removal of a portion of the glass layer circumscribed by the closed contour.

44. A method of laser processing comprising:
forming a laser beam focal line in a workpiece, the laser beam focal line being formed from a pulsed laser beam,
the workpiece having a glass layer, the laser beam focal line generating an induced absorption within the workpiece, the induced absorption producing a defect line along the laser beam focal line within the workpiece;
translating the workpiece and the laser beam relative to each other along a contour, thereby forming a plurality of defect lines along the contour; and
directing an infrared laser along the contour.

45. The method of claim 44, wherein the contour is a closed contour.

46. The method of claim 44, wherein the infrared laser effects fracture of the workpiece along the contour.

47. The method of claim 46, wherein the contour is closed and the fracture effects separation of a part from the workpiece.

48. A glass component processed by the method of claim 1.

49. A glass component processed by the method of claim 28.

50. A glass component processed by the method of claim 34.

51. The method of claim 1, wherein the defect line extends through the full thickness of the first layer.

52. The method of claim 1, wherein the induced absorption does not occur in the second layer.

53. The method of claim 28, wherein the defect line is present in at least two of the plurality of glass layers.

54. The method of claim 34, wherein the defect line is present in at least two of the plurality of glass layers.

55. The method of claim 43, wherein the laser beam focal line is formed in the glass layer.

56. The method of claim 44, wherein the laser beam focal line is formed in the glass layer.

57. A method of forming a perforation comprising:
(i) providing a multilayer structure, the multilayer structure including a beam disruption element disposed on a carrier and a first layer disposed on the beam disruption element;
(ii) focusing a laser beam with wavelength λ on a first portion of the first layer, the first layer being transparent to the wavelength λ, the focusing forming a region of high laser intensity within the first layer, the high laser intensity being sufficient to effect nonlinear absorption within the region of high laser intensity, the beam disruption element preventing occurrence of nonlinear absorption in the carrier material or other layer disposed on the side of the beam disruption element opposite the first layer, the nonlinear absorption enabling transfer of energy from the laser beam to the first layer within the region of high intensity, the transfer of energy causing creation of a first perforation in the first layer in the region of high laser intensity, the first perforation extending in the direction of propagation of the laser beam;
(iii) focusing the laser beam on a second portion of the first layer; and
(iv) repeating step (ii) to form a second perforation in the second portion of the substrate, the second perforation extending in the direction of propagation of the laser beam, the beam disruption element preventing occurrence of nonlinear absorption in the carrier material or other layer disposed on the side of the beam disruption element opposite the first layer during the formation of the second perforation.
